(19) United States
(12) Patent Application Publication
(10) Pub. No.: US 2026/0247832 A1
(43) Pub. Date: Aug. 20, 2026

(54) Display Panel and Manufacturing Method Thereof, and Display Device

(71) Applicant: BOE TECHNOLOGY GROUP CO., LTD., Beijing (CN)

(72) Inventors: Meng Sun, Beijing (CN); Shuyun Xu, Beijing (CN); Haidong Wu, Beijing (CN); Xu Liu, Beijing (CN)

(21) Appl. No.: 18/869,779

(22) PCT Filed: Aug. 12, 2024
(86) PCT No.: PCT/CN2024/111528

§ 371 Date: Nov. 26, 2024

(30) Foreign Application Priority Data
Sep. 5, 2023 (CN) 202311142466.0

(51) Int. Cl. H10K 59/80; H10K 59/12; H10K 71/60; H10K 102/00; H10K 102/20

(52) U.S. Cl. CPC H10K 59/80521; H10K 59/1201; H10K 59/80523; H10K 71/60; H10K 2102/20; H10K 2102/351

(57) ABSTRACT

A display panel includes an array substrate and a cathode layer. The display panel has a display region. The cathode layer is disposed on the array substrate. The cathode layer includes a first sub-portion and a second sub-portion surrounding the first sub-portion, and both the first sub-portion and the second sub-portion are located in the display region. A resistance per unit length of the first sub-portion is less than a resistance per unit length of the second sub-portion.

### CROSS-REFERENCE TO RELATED APPLICATIONS

This application is the United States national phase of International Patent Application No. PCT/CN2024/111528, filed Aug. 12, 2024, and claims priority to Chinese Patent Application No. 202311142466.0, filed Sep. 5, 2023, the disclosures of which are hereby incorporated by reference in their entireties.

### BACKGROUND OF THE INVENTION

### Field of the Invention

The present disclosure relates to the field of display technologies, and in particular, to a display panel and a manufacturing method thereof, and a display device.

### DESCRIPTION OF RELATED ART

Organic light-emitting diodes (OLEDs) have been widely applied in the display field due to their advantages such as self-luminous, low driving voltage, high luminous efficiency, fast response and flexible display.

### SUMMARY OF THE INVENTION

Embodiments of the present disclosure provide the following technical solutions.

In an aspect, a display panel is provided. The display panel includes an array substrate and a cathode layer. The display panel has a display region. The cathode layer is disposed on the array substrate. The cathode layer includes a first sub-portion and a second sub-portion surrounding the first sub-portion, both the first sub-portion and the second sub-portion are located in the display region, and a resistance per unit length of the first sub-portion is less than a resistance per unit length of the second sub-portion.

In some embodiments, a thickness of the first sub-portion is greater than a thickness of the second sub-portion.

In some embodiments, the cathode layer includes a first conductive layer and a second conductive layer. The first conductive layer is disposed on the array substrate and located in the display region; the first conductive layer includes a third sub-portion and the second sub-portion surrounding the third sub-portion. The second conductive layer is disposed on a side of the first conductive layer away from the array substrate; an orthographic projection of the second conductive layer on the array substrate coincides with an orthographic projection of the third sub-portion on the array substrate. The second conductive layer and the third sub-portion constitute the first sub-portion.

In some embodiments, the display panel further includes a plurality of light-emitting devices. The plurality of light-emitting devices are disposed on the array substrate. In a direction perpendicular to the array substrate and away from the array substrate, a light-emitting device of the plurality of light-emitting devices includes a light-emitting function layer and a cathode that are stacked; the cathode is located in the cathode layer, and an orthographic projection of the second conductive layer on the array substrate partially overlaps with orthographic projections of a plurality of light-emitting function layers included in the plurality of light-emitting devices on the array substrate.

In some embodiments, from a center of the display region to a border of the display region, a thickness of the cathode layer gradually decreases.

In some embodiments, a material of the first sub-portion includes at least one of aluminum, iron, tin, magnesium, copper, silver and gold, and/or a material of the second sub-portion includes at least one of aluminum, iron, tin, magnesium, copper, silver and gold.

In some embodiments, an electrical conductivity of the first sub-portion is greater than an electrical conductivity of the second sub-portion.

In some embodiments, a material of the first sub-portion includes at least one of copper, silver and gold, and a material of the second sub-portion includes at least one of aluminum, iron, tin and magnesium.

In some embodiments, from a center of the display region to a border of the display region, an electrical conductivity of the cathode layer gradually decreases.

In some embodiments, a material of the cathode layer includes a host material and a dopant material. An electrical conductivity of the host material is greater than an electrical conductivity of the dopant material, and from the center of the display region to the border of the display region, a ratio of the host material to the dopant material decreases. Alternatively, the electrical conductivity of the host material is less than the electrical conductivity of the dopant material, and from the center of the display region to the border of the display region, the ratio of the host material to the dopant material increases.

In some embodiments, a thickness of the first sub-portion is greater than or equal to a thickness of the second sub-portion.

In another aspect, a display device is provided. The display device includes: the display panel according to any one of the above embodiments.

In yet another aspect, a manufacturing method of a display panel is provided. The display panel has a display region. The manufacturing method includes: providing an array substrate, the array substrate including a first region and a second region surrounding the first region, and both the first region and the second region being located in the display region; and forming a first sub-portion in the first region and forming a second sub-portion in the second region, the second sub-portion being connected to the first sub-portion to constitute a cathode layer, and a resistance per unit length of the first sub-portion being less than a resistance per unit length of the second sub-portion.

In some embodiments, forming the first sub-portion in the first region and forming the second sub-portion in the second region includes: forming a first conductive layer on the array substrate, the first conductive layer including a third sub-portion located in the first region and the second sub-portion located in the second region; and forming a second conductive layer on a side of the first conductive layer away from the array substrate, an orthographic projection of the second conductive layer on the array substrate coinciding with an orthographic projection of the third sub-portion on the array substrate, and the second conductive layer and the third sub-portion constituting the first sub-portion.

In some embodiments, forming the first conductive layer on the array substrate includes: placing a first mask on a side of the array substrate, an orthographic projection of a first opening of the first mask on the array substrate covering the first region and the second region; and forming the first conductive layer through the first opening.

In some embodiments, forming the second conductive layer on the side of the first conductive layer away from the array substrate includes: covering an edge region of a first opening of a first mask; placing the first mask of which the edge region is covered on the side of the first conductive layer away from the array substrate, an orthographic projection of the first opening on the array substrate covering the first region and the second region, and an orthographic projection of the edge region on the array substrate covering the second region and exposing the first region; and forming the second conductive layer through the first opening.

In some embodiments, forming the second conductive layer on the side of the first conductive layer away from the array substrate includes: forming a first metal inhibition layer on the side of the first conductive layer away from the array substrate, an orthographic projection of the first metal inhibition layer on the array substrate covering the second region and exposing the first region; placing a first mask on the side of the first conductive layer away from the array substrate, an orthographic projection of a first opening of the first mask on the array substrate covering the first region and the second region; forming the second conductive layer through the first opening and the first metal inhibition layer; and removing the first metal inhibition layer.

In some embodiments, forming the second conductive layer on the side of the first conductive layer away from the array substrate includes: forming a metal promotion layer on the first conductive layer, an orthographic projection of the metal promotion layer on the array substrate covering the first region and exposing the second region; placing a first mask on a side of the first conductive layer and the metal promotion layer away from the array substrate, an orthographic projection of a first opening of the first mask on the array substrate covering the first region and the second region; and forming the second conductive layer through the first opening and the metal promotion layer, the metal promotion layer being configured such that the orthographic projection of the second conductive layer on the array substrate is located in the first region and exposes the second region.

In some embodiments, forming the second conductive layer on the side of the first conductive layer away from the array substrate includes: placing a second mask on the side of the first conductive layer away from the array substrate, an orthographic projection of a second opening of the second mask on the array substrate covering the first region and exposing the second region; and forming the second conductive layer through the second opening.

In some embodiments, forming the first sub-portion in the first region includes: placing a third mask on a side of the array substrate, the third mask having a third opening region, and an orthographic projection of the third opening region on the array substrate covering the first region and exposing the second region; and forming the first sub-portion through the third opening region.

In some embodiments, forming the first sub-portion in the first region includes: forming a second metal inhibition layer on the array substrate, an orthographic projection of the second metal inhibition layer on the array substrate covering the second region and exposing the first region; forming the first sub-portion through the second metal inhibition layer; and removing the second metal inhibition layer.

In some embodiments, forming the second sub-portion in the second region includes: placing a fourth mask on a side of the array substrate, the fourth mask having a fourth opening region, and an orthographic projection of the fourth opening region on the array substrate covering the second region and exposing the first region; and forming the second sub-portion through the fourth opening region, a thickness of the first sub-portion being greater than a thickness of the second sub-portion, and/or an electrical conductivity of the first sub-portion being greater than an electrical conductivity of the second sub-portion.

In some embodiments, forming the second sub-portion in the second region includes: forming a third metal inhibition layer on the array substrate, an orthographic projection of the third metal inhibition layer on the array substrate covering the first region and exposing the second region; forming the second sub-portion through the third metal inhibition layer, a thickness of the first sub-portion being greater than a thickness of the second sub-portion, and/or an electrical conductivity of the first sub-portion being greater than an electrical conductivity of the second sub-portion; and removing the third metal inhibition layer.

In some embodiments, forming the first sub-portion in the first region and forming the second sub-portion in the second region includes: placing a fifth mask on a side of the array substrate, the fifth mask having a fifth opening region located in the display region; and gradually increasing an area of the fifth opening region and depositing a cathode material on the array substrate through the fifth opening region by evaporation to form the cathode layer, a thickness of the cathode layer gradually decreasing from a center of the display region to a border of the display region.

In some embodiments, while increasing the area of the fifth opening region, the manufacturing method further includes: gradually reducing an electrical conductivity of the cathode material to be deposited by evaporation; the cathode material including a host material and a dopant material; in a case where an electrical conductivity of the host material is greater than an electrical conductivity of the dopant material, gradually reducing a ratio of the host material to the dopant material; and in a case where the electrical conductivity of the host material is less than the electrical conductivity of the dopant material, gradually increasing the ratio of the host material to the dopant material.

### BRIEF DESCRIPTION OF THE DRAWINGS

In order to describe the technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display panel, in accordance with some embodiments;

FIG. 2 is a sectional view taken along the section line A-A in FIG. 1;

FIG. 3 is a structural diagram of a light-emitting function layer of a display panel, in accordance with some embodiments;

FIG. 4 is a diagram showing an energy transferring process of a light-emitting device, in accordance with some embodiments;

FIG. 5 is a structural diagram of a cathode layer including a first sub-portion and a second sub-portion, in accordance with some embodiments;

FIG. 6 is a sectional view taken along the section line B-B in FIG. 5;

FIG. 7 is a diagram showing a current model of resistances of a first sub-portion and a second sub-portion, in accordance with some embodiments;

FIG. 8 is a structural diagram of a cathode layer with a gradually decreasing thickness, in accordance with some embodiments;

FIG. 9 is a sectional view taken along the section line C-C in FIG. 8;

FIG. 10 is another sectional view taken along the section line B-B in FIG. 5;

FIG. 11 is yet another sectional view taken along the section line B-B in FIG. 5;

FIG. 12 is a structural diagram of a cathode layer with a gradually decreasing ratio of a host material to a dopant material, in accordance with some embodiments;

FIG. 13 is a sectional view taken along the section line D-D in FIG. 12;

FIG. 14 is a structural diagram of a cathode layer with a gradually increasing ratio of a host material to a dopant material, in accordance with some embodiments;

FIG. 15 is a sectional view taken along the section line E-E in FIG. 14;

FIG. 16 is a structural view of a light-emitting device of a display panel, in accordance with some embodiments; and

FIGS. 17 to 29 are each a diagram showing steps of a manufacturing method of a display panel, in accordance with some embodiments.

### DESCRIPTION OF THE INVENTION

The technical solutions in some embodiments of the present disclosure will be clearly and completely described below in conjunction with the accompanying drawings. Obviously, the embodiments to be described are merely some but not all embodiments of the present disclosure. All other embodiments obtained by a person of ordinary skill in the art based on the embodiments of the present disclosure should be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, a feature defined with “first” or “second” may explicitly or implicitly include one or more of the feature. In the description of the embodiments of the present disclosure, the term “a/the plurality of” means two or more unless otherwise specified.

Some embodiments may be described using the term “connected” and its derivatives. The term “connected” should be understood in a broad sense, for example, the term “connected” may represent a fixed connection, or a detachable connection, or a one-piece connection; alternatively, the term “connected” may represent a direct connection, or an indirect connection through an intermediate medium.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

The term such as “substantially” as used herein includes a stated value and an average value within an acceptable range of deviation of a particular value. The acceptable range of deviation may be determined, for example, by a person of ordinary skill in the art, considering measurement in question and errors (i.e., limitations of a measurement system) associated with measurement of a particular quantity.

The term such as “perpendicular” or “equal” as used herein includes a stated condition and a condition similar to the stated condition within an acceptable range of deviation. The acceptable range of deviation may be determined, for example, by a person of ordinary skill in the art, considering measurement in question and errors (i.e., limitations of a measurement system) associated with measurement of a particular quantity. For example, the term “perpendicular” includes absolute perpendicularity and approximate perpendicularity, and an acceptable range of deviation of the approximate perpendicularity may be a deviation within 5°; the term “equal” includes absolute equality and approximate equality, and an acceptable range of deviation of the approximate equality may be a difference between two equals being less than or equal to 5% of either of the two equals.

It will be understood that, in a case where a layer or element is referred to as being on another layer or substrate, it may be that the layer or element is directly on the another layer or substrate, or there may be an intermediate layer between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including deviations in shape due to, for example, manufacturing. For example, an etched region shown to have a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

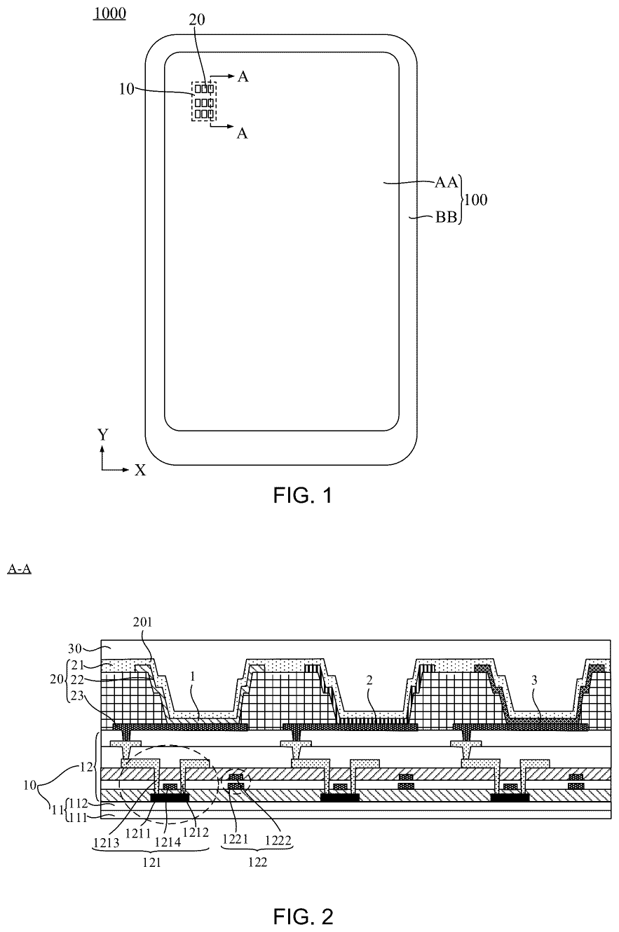

Some embodiments of the present disclosure provide a display device 1000, and as shown in FIG. 1, the display device 1000 may be any device that displays images whether in motion (e.g., videos) or stationary (e.g., static images), and whether textual or graphical. For example, the display device 1000 may be any product or component having a display function, such as a television, a notebook computer, a tablet computer, a mobile phone, a personal digital assistant (PDA), a navigator, a wearable device, an augmented reality (AR) device, or a virtual reality (VR) device.

The display device 1000 may be an organic light-emitting diode (OLED) display device, a quantum dot light-emitting diode (QLED) display device, or an active matrix organic light-emitting diode (AMOLED) display device. The embodiments of the present disclosure will be described by taking an example in which the display device is an OLED display device.

Some embodiments of the present disclosure will be described below by taking an example in which the display device 1000 is an organic light-emitting diode display device 1000, but the embodiments of the present disclosure are not limited thereto, and any other display device 1000 may also be taken into consideration as long as the same technical concept is applied.

As shown in FIG. 1, the display device 1000 includes a display panel 100, and the display panel 100 has a display region AA and a peripheral region BB located on at least a side of the display region AA. FIG. 1 is illustrated by taking an example in which the peripheral region BB surrounds the display region AA.

As shown in FIG. 1, the display region AA is a region where images are displayed, the peripheral region BB is a region where no image is displayed, and the peripheral region BB is configured to be provided with driving circuits, such as a gate driving circuit and a source driving circuit.

As shown in FIG. 2, the display panel 100 includes an array substrate 10, and a plurality of light-emitting devices 20 and an encapsulation layer 30 that are disposed on the array substrate 10.

As shown in FIG. 2, the encapsulation layer 30 is located on a side of the plurality of light-emitting devices 20 away from the array substrate 10. The encapsulation layer 30 may be an encapsulation film. In some embodiments, the encapsulation layer 30 may include one layer of encapsulation film, or two or more layers of encapsulation films that are stacked. For example, the encapsulation layer 30 includes three layers of encapsulation films that are sequentially stacked.

In a case where the encapsulation layer 30 includes three layers of encapsulation films that are sequentially stacked, a material of an encapsulation film located in the middle layer is an organic material, and materials of encapsulation films located on both sides are inorganic materials. The organic material may be, for example, polymethyl methacrylate (PMMA) or polyimide (PI).

As shown in FIG. 2, the array substrate 10 includes a substrate 11 and pixel circuits 12 disposed on the substrate 11.

For example, the substrate 11 may be a flexible substrate 11. As an example, the flexible substrate 11 may be a polyethylene terephthalate (PET) substrate 11, a polyethylene naphthalate two formic acid glycol ester (PEN) substrate or a polyimide substrate 11, etc.

For example, the substrate 11 may be a rigid substrate 11. As an example, the rigid substrate 11 may be a glass substrate 11 or a polymethyl methacrylate substrate 11.

It will be noted that the substrate 11 may be of a single-layer structure or a multi-layer structure. For example, in a case where the substrate 11 is of a multi-layer structure, as shown in FIG. 2, the substrate 11 may include a base 111 and a buffer layer 112 disposed on the base 111. A material of the buffer layer 112 may include silicon oxide or silicon nitride, and the material and structure of the substrate 11 are not specifically limited in the embodiments of the present disclosure.

As shown in FIG. 2, a pixel circuit 12 includes a plurality of thin film transistors 121 and storage capacitor(s) 122.

In some embodiments, the thin film transistor 121 is, for example, an oxide thin film transistor. The oxide thin film transistor has a relatively high carrier mobility, which can improve the response speed of the thin film transistor 121. For example, the pixel circuit 12 may be of a 2T1C, 5T2C, 6T1C, 6T2C, 7T1C, 7T2C or 9T2C structure, which will not be enumerated in the embodiments of the present disclosure. For instance, the pixel circuit 12 is of a 7T1C structure. The pixel circuit 12 being of an “aTbC” structure means that the number of thin film transistors 121 included in the pixel circuit 12 is “a”, and the number of storage capacitors 122 included in the pixel circuit 12 is “b”.

A thin film transistor 121 includes an active layer 1211, a source 1212, a drain 1213 and a gate 1214, and the source 1212 and the drain 1213 are respectively in contact with the active layer 1211. A storage capacitor 122 includes a first plate 1221 and a second plate 1222 that are arranged opposite to each other.

It will be noted that the source 1212 and the drain 1213 may be interchanged; that is, the reference number “1212” in FIG. 2 represents the drain, and the reference number “1213” in FIG. 2 represents the source.

As shown in FIG. 1, the plurality of light-emitting devices 20 are located in the display region AA. For example, the plurality of light-emitting devices 20 may be arranged in multiple rows and columns, a row of light-emitting devices 20 include multiple light-emitting devices 20 arranged in a first direction X, and a column of light-emitting devices 20 include multiple light-emitting devices 20 arranged in a second direction Y. The first direction X is substantially perpendicular to the second direction Y.

The plurality of light-emitting devices 20 may include light-emitting devices 20 emitting light of a first color, light-emitting devices 20 emitting light of a second color, and light-emitting devices 20 emitting light of a third color. The first color, the second color, and the third color are three primary colors. For example, the first color is red, the second color is blue, and the third color is green, which is not specifically limited in the embodiments of the present disclosure.

As shown in FIG. 2, a light-emitting device 20 includes a cathode 21, a light-emitting function layer 22 and an anode 23. The anode 23 may be electrically connected to, for example, a source of a thin film transistor 121 among the plurality of thin film transistors 121 that serves as a driving transistor.

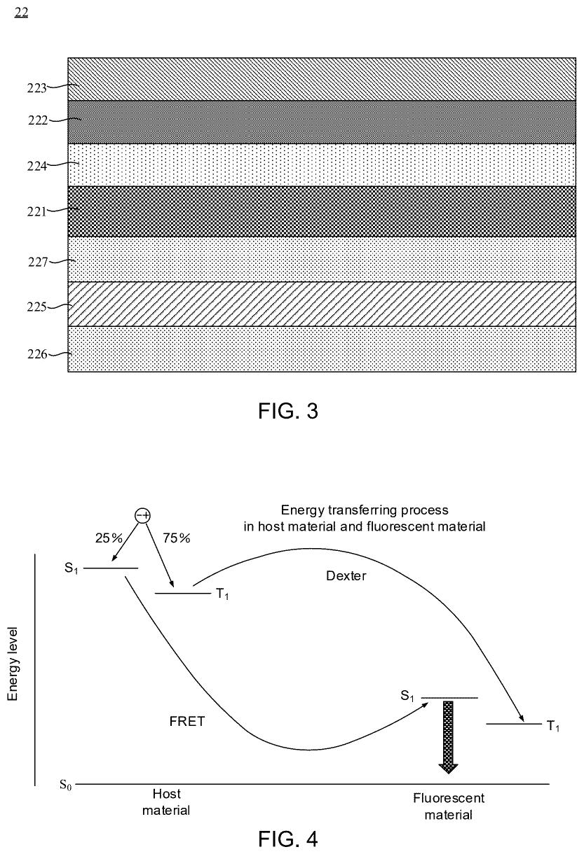

As shown in FIG. 3, the light-emitting function layer 22 may only include a light-emitting layer 221. Alternatively, besides the light-emitting layer 221, the light-emitting function layer 22 may further include at least one of an electron transporting layer (ETL) 222, an electron injection layer (EIL) 223, a hole blocking layer (HBL) 224, a hole transporting layer (HTL) 225, a hole injection layer (HIL) 226 and an electron blocking layer (EBL) 227.

In some embodiments, as shown in FIG. 2, the light-emitting function layers 22 include a plurality of red light-emitting function layers 1, a plurality of green light-emitting function layers 2, and a plurality of blue light-emitting function layers 3.

A red light-emitting function layer includes a host material and a red fluorescent material, so that the red light-emitting function layer can emit red light. For example, a doping ratio of the red fluorescent material is in a range of 2% to 4%, inclusive. For instance, the doping ratio of the red fluorescent material is 2%, 2.2%, 2.5%, 2.6%, 2.7%, 2.9%, 3.1%, 3.2%, 3.5%, 3.8% or 4%, which will not be enumerated in the embodiments of the present disclosure.

A green light-emitting function layer includes a host material and a green fluorescent material, so that the green light-emitting function layer can emit green light. For example, a doping ratio of the green fluorescent material is in a range of 8% to 10%, inclusive. For instance, the doping ratio of the green fluorescent material is 8%, 8.1%, 8.3%, 8.4%, 8.6%, 8.8%, 9%, 9.2%, 9.5%, 9.6%, 9.8% or 10%, which will not be enumerated in the embodiments of the present disclosure.

A blue light-emitting function layer includes a host material and a blue fluorescent material, so that the blue light-emitting function layer can emit blue light. For example, a doping ratio of the blue fluorescent material is in a range of 1% to 5%, inclusive. For instance, the doping ratio of the blue fluorescent material is 1%, 1.1%, 1.3%, 1.4%, 1.6%, 1.8%, 2%, 2.5%, 2.8%, 3%, 3.2%, 3.5%, 3.8%, 4%, 4.2%, 4.6% or 5%, which will not be enumerated in the embodiments of the present disclosure.

The plurality of red light-emitting function layers, the plurality of green light-emitting function layers and the plurality of blue light-emitting function layers cooperate with each other to realize full-color display of the display panel. For example, the plurality of red light-emitting function layers, the plurality of blue light-emitting function layers and the plurality of green light-emitting function layers cooperate with each other to enable the display panel 100 to display a white picture.

In some embodiments, a thickness of the light-emitting layer 221 is in a range of 20 nm to 40 nm, inclusive. For example, the thickness of the light-emitting layer 221 is 20 nm, 22 nm, 25 nm, 26 nm, 28 nm, 29 nm, 31 nm, 34 nm, 35 nm, 38 nm or 40 nm, which will not be enumerated in the embodiments of the present disclosure.

A material of the light-emitting layer 221 includes one or more organic compounds. The structural formulas of the organic compounds are shown below.

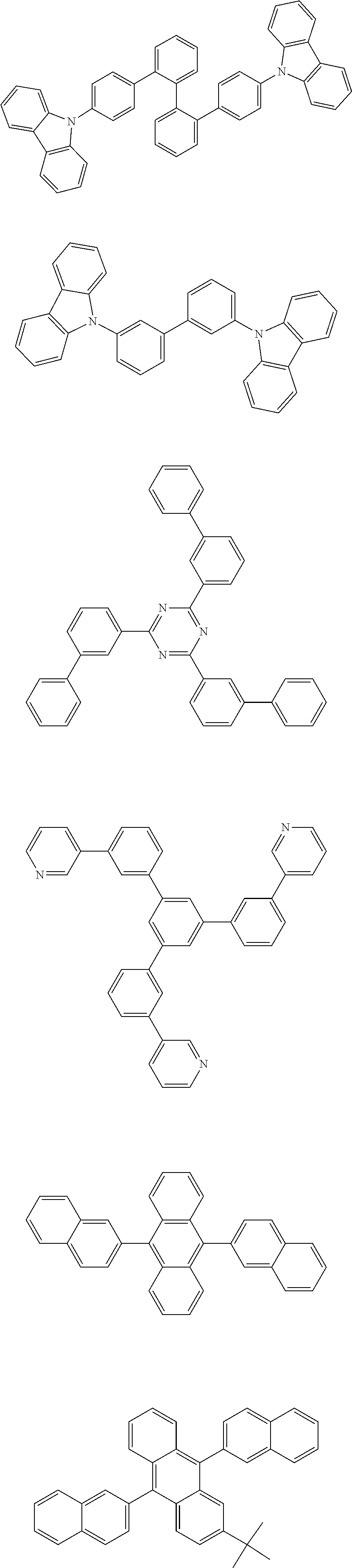

A thickness of the electron transporting layer 222 is in a range of 20 nm to 35 nm, inclusive. For example, the thickness of the electron transporting layer 222 is 20 nm, 22 nm, 25 nm, 26 nm, 28 nm, 29 nm, 31 nm, 34 nm or 35 nm, which will not be enumerated in the embodiments of the present disclosure.

A material of the electron transporting layer 222 includes one or more organic compounds. The organic compounds include lithium fluoride or compounds having the structural formulas shown below.

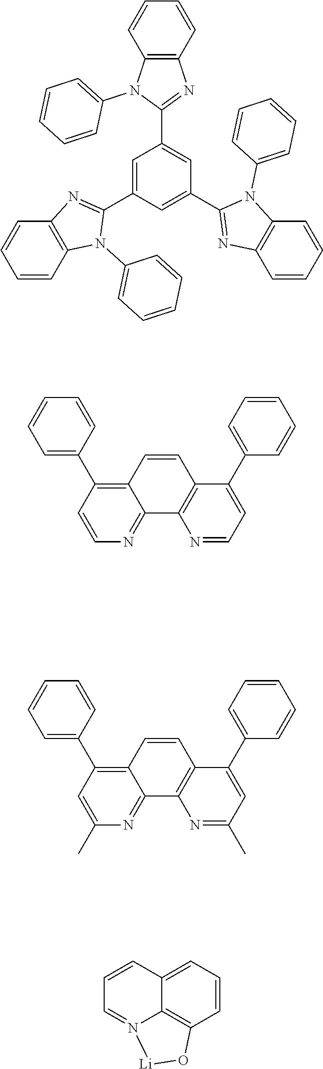

A thickness of the electron injection layer 223 is in a range of 0.5 nm to 3 nm, inclusive. For example, the thickness of the electron injection layer 223 is 0.5 nm, 0.6 nm, 0.8 nm, 0.9 nm, 1 nm, 1.5 nm, 2 nm, 2.2 nm, 2.5 nm or 3 nm, which will not be enumerated in the embodiments of the present disclosure.

A material of the electron injection layer 223 includes one or more organic compounds. The organic compounds include lithium fluoride, ytterbium or a compound having the structural formula shown below.

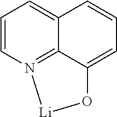

A thickness of the electron blocking layer 227 is in a range of 10 nm to 80 nm, inclusive. For example, the thickness of the electron blocking layer 227 is 10 nm, 14 nm, 20 nm, 28 nm, 32 nm, 40 nm, 50 nm, 65 nm, 70 nm or 80 nm, which will not be enumerated in the embodiments of the present disclosure.

A material of the electron blocking layer 227 includes one or more organic compounds. The structural formulas of the organic compounds are shown below.

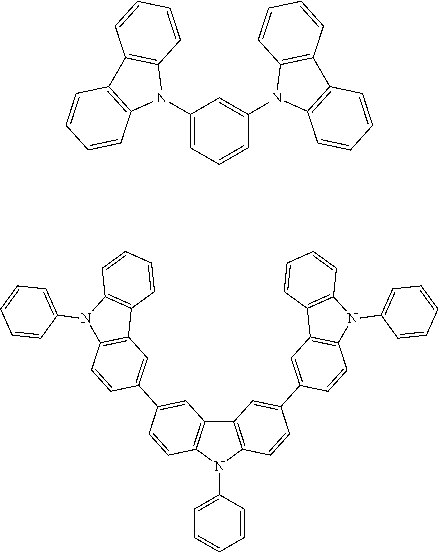 [SMILES: c1cc(-n2c3ccccc3c3ccccc32)cc(-n2c3ccccc3c3ccccc32)c1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

A thickness of the hole transporting layer 225 is in a range of 100 nm to 130 nm, inclusive. For example, the thickness of the hole transporting layer 225 is 100 nm, 102 nm, 105 nm, 108 nm, 110 nm, 113 nm, 117 nm, 120 nm, 121 nm, 124 nm, 126 nm or 130 nm, which will not be enumerated in the embodiments of the present disclosure.

A material of the hole transporting layer 225 includes one or more organic compounds. The structural formulas of the organic compounds are shown below.

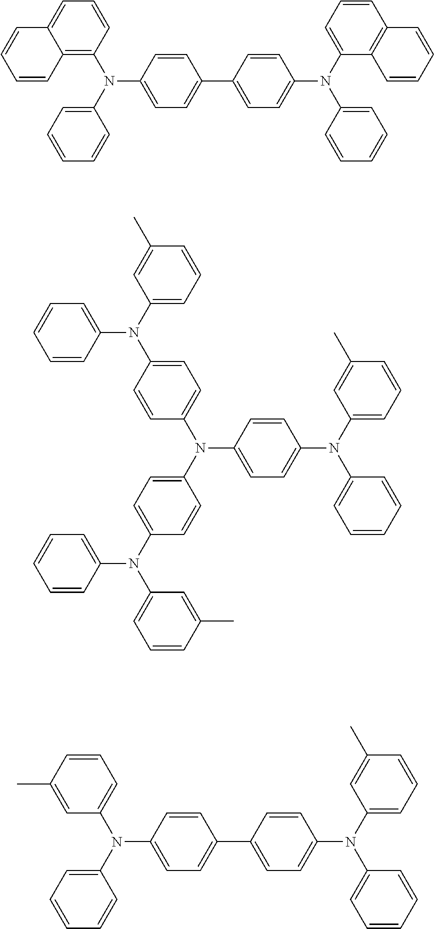 [SMILES: c1ccc(N(c2ccc(-c3ccc(N(c4ccccc4)c4cccc5ccccc45)cc3)cc2)c2cccc3ccccc23)cc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; Cc1cccc(N(c2ccccc2)c2ccc(-c3ccc(N(c4ccccc4)c4cccc(C)c4)cc3)cc2)c1]

A thickness of the hole injection layer 226 is in a range of 5 nm to 30 nm, inclusive. For example, the thickness of the hole injection layer 226 is 5 nm, 6 nm, 8 nm, 10 nm, 11 nm, 14 nm, 15 nm, 16 nm, 19 nm, 22 nm, 25 nm, 28 nm or 30 nm, which will not be enumerated in the embodiments of the present disclosure.

A material of the hole injection layer 226 includes one or more organic compounds. The structural formulas of the organic compounds are shown below.

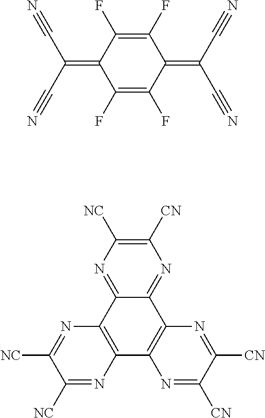 [SMILES: N#CC(C#N)=c1c(F)c(F)c(=C(C#N)C#N)c(F)c1F ; N#Cc1nc2c3nc(C#N)c(C#N)nc3c3nc(C#N)c(C#N)nc3c2nc1C#N]

A thickness of the hole blocking layer 224 is in a range of 5 nm to 10 nm, inclusive. For example, the thickness of the hole blocking layer 224 is 5 nm, 5.6 nm, 5.8 nm, 6 nm, 6.1 nm, 6.4 nm, 7 nm, 7.2 nm, 7.5 nm, 7.9 nm, 8 nm, 8.5 nm, 9 nm or 10 nm, which will not be enumerated in the embodiments of the present disclosure.

A material of the hole blocking layer 224 includes one or more organic compounds. The structural formulas of the organic compounds are shown below.

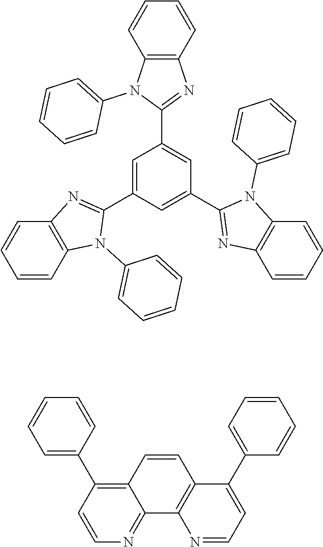 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(-c2ccnc3c2ccc2c(-c4ccccc4)ccnc23)cc1]

The light-emitting principle of the light-emitting device 20 will be exemplarily described below. As shown in FIG. 4, the light-emitting function layer 22 includes a host material and a fluorescent material. The anode 23 provides holes to the light-emitting function layer 22, and the holes are injected into the highest occupied molecular orbital (HOMO) in the host material and move therein. The cathode 21 provides electrons to the light-emitting function layer 22, and the electrons are injected into the lowest unoccupied molecular orbital (LUMO) and move therein.

As shown in FIG. 4, the combination of holes and electrons can enable the organic molecules in the host material (the host material does not emit light, the function of which is to transfer energy to the fluorescent material to excite the organic molecules in the fluorescent material to transition from the ground state to the excited state) to transition from the ground state S₀ to the excited state to form excitons. The excitons are classified into two types, one is singlet exciton S₁, and the other is triplet exciton T₁. According to the spin statistic rules for electrons, the ratio of generated singlet excitons S₁ to generated triplet excitons T₁ is 1:3. According to the principles of quantum mechanics, the electron-hole pair in the singlet exciton S₁ have opposite spin directions and can transition to the ground state S₀, while the electron-hole pair in the triplet exciton T₁ have a same spin direction and cannot transition to the ground state S₀. The energy difference between the triplet exciton T₁ and the singlet excitons S₁ in the host material is relatively large, and it is difficult for the triplet exciton T₁ to transition to the singlet exciton S₁ through reverse intersystem crossing (RISC). The singlet excitons S₁ in the host material can enable the organic molecules in the fluorescent material to accept energy and transition from the ground state S₀ to the excited state through Foster resonance energy transfer (FRET), so that the organic molecules in the fluorescent material form singlet excitons S₁. The triplet excitons T₁ in the host material can enable the organic molecules in the fluorescent material to accept energy and transition from the ground state S₀ to the excited state through Dexter excitation transfer (Dexter), so that the organic molecules in the fluorescent material form triplet excitons T₁. The singlet excitons S₁ in the fluorescent material are unstable and may easily return to the ground state S₀ from the excited state. The singlet excitons S₁ in the fluorescent material return from the excited state to the ground state S₀, and the fluorescent material emits light at the same time.

In some embodiments, as shown in FIG. 2, cathodes 21 of the plurality of light-emitting devices 20 are connected together to constitute a cathode layer 201; that is, the cathodes 21 are located in the cathode layer 201. In this way, the area of the cathode layer 201 is relatively large, and in a case where the cathode layer 201 is formed by using a mask to deposit the material of the cathodes 21 by evaporation, the opening of the mask corresponding to the cathode layer 201 is relatively large, so that the difficulty of manufacturing the mask may be reduced.

In the related art, when the current flows from the anodes to the cathodes, there is a voltage difference on the cathode layer, which will result in poor brightness uniformity of the display panel.

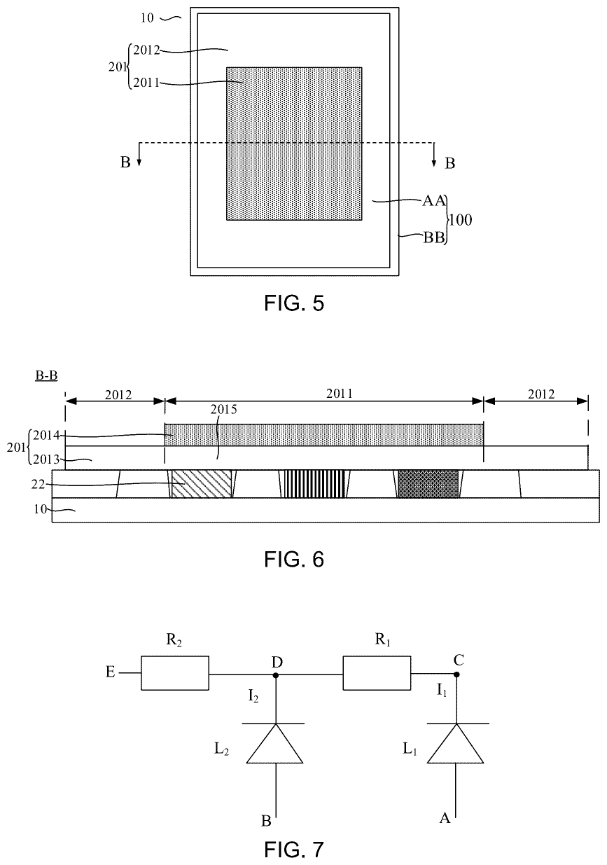

In order to solve the above problem, as shown in FIGS. 5 and 6, the cathode layer 201 provided in the embodiments of the present disclosure includes a first sub-portion 2011 and a second sub-portion 2012 surrounding the first sub-portion 2011, and both the first sub-portion 2011 and the second sub-portion 2012 are located in the display region AA.

FIG. 7 shows a current model of the resistances of the first sub-portion 2011 and the second sub-portion 2012. As shown in FIG. 7, the resistance of the first sub-portion 2011 is R₁, and a light-emitting device 20 corresponding to the first sub-portion 2011 is a first light-emitting device L₁; the resistance of the second sub-portion 2012 is R₂, and a light-emitting device 20 corresponding to the second sub-portion 2012 is a second light-emitting device L₂. The current passing through the first light-emitting device L₁ is I₁, and the current passing through the second light-emitting device L₂ is 12. An anode voltage of the first light-emitting device L₁ is U_{A}, and an anode voltage of the second light-emitting device L₂ is U_{B}.

The embodiments of the present disclosure will be described by taking an example in which the first light-emitting device L₁ and the second light-emitting device L₂ included in the display panel 100 are at a same gray scale, which means that the anode voltage U_{A} of the first light-emitting device L₁ is equal to the anode voltage U_{B} of the second light-emitting device L₂.

Referring to FIG. 7, a unit resistance (also referred to as resistance per unit length herein) of the first sub-portion 2011 is less than a unit resistance of the second sub-portion 2012, so that the resistance R₁ of the first sub-portion 2011 is small, and thus, the total resistance of the first sub-portion 2011, the second sub-portion 2012, the first light-emitting device L₁ and the second light-emitting device L₂ is reduced. In this way, the total current I₁+I₂ passing through the second sub-portion 2012 with the resistance of R₂ is reduced, so that the voltage drop U_{DE} on the second sub-portion 2012 is increased; that is, the voltage drop UBD on the second light-emitting device L₂ is reduced, and the voltage U_{D} at the node D is increased. As a result, the current I₂ passing through the second light-emitting device L₂ is reduced, and the current I₁ passing through the first light-emitting device L₁ is increased, the voltage drop U_{AC} on the first light-emitting device L₁ is increased, and the voltage U_{C} at the node C is reduced (it will be noted that the voltage U_{C} at the node C is always greater than the voltage U_{D} at the node D).

The voltage U_{D} at the node D is increased and the voltage U_{C} at the node C is reduced, so that the voltage difference between the node D and the node C is reduced, which means that the voltage difference between the first sub-portion 2011 and the second sub-portion 2012 is reduced, so that the brightness uniformity of the display panel 100 is improved.

In some embodiments, as shown in FIG. 6, a thickness of the first sub-portion 2011 is greater than a thickness of the second sub-portion 2012, so that a cross-sectional area of the first sub-portion 2011 is greater than a cross-sectional area of the second sub-portion 2012. As a result, the unit resistance of the first sub-portion 2011 is less than the unit resistance of the second sub-portion 2012, which may reduce the voltage difference between the first sub-portion 2011 and the second sub-portion 2012, so as to improve the brightness uniformity of the display panel 100.

In some examples, as shown in FIG. 6, the cathode layer 201 includes a first conductive layer 2013 and a second conductive layer 2014. The first conductive layer 2013 is disposed on the array substrate 10. The first conductive layer 2013 is located in the display region AA, and the first conductive layer 2013 includes a third sub-portion 2015 and the second sub-portion 2012 surrounding the third sub-portion 2015. The second conductive layer 2014 is disposed on a side of the first conductive layer 2013 away from the array substrate 10, an orthographic projection of the second conductive layer 2014 on the array substrate 10 coincides with an orthographic projection of the third sub-portion 2015 on the array substrate 10, and the second conductive layer 2014 and the third sub-portion 2015 constitute the first sub-portion 2011.

For example, as shown in FIG. 6, the orthographic projection of the second conductive layer 2014 on the array substrate 10 partially overlaps with orthographic projections of a plurality of light-emitting function layers 22 on the array substrate 10.

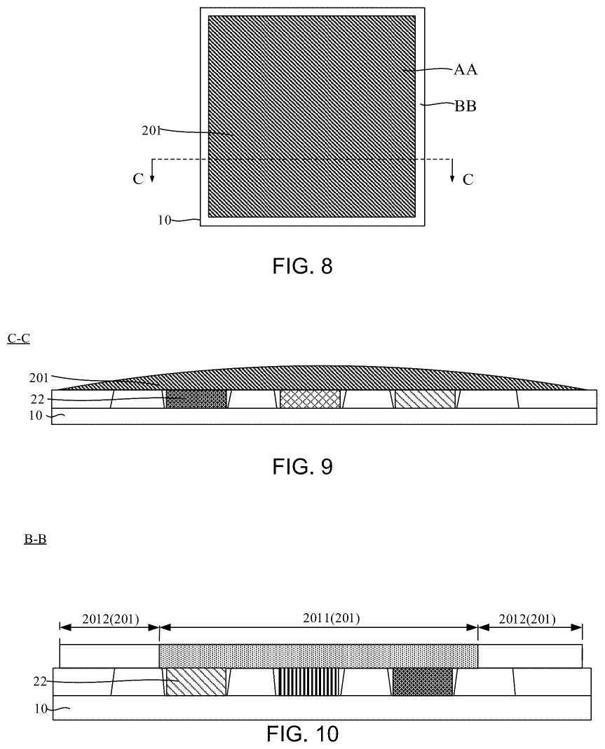

In some embodiments, as shown in FIGS. 8 and 9, from the center of the display region AA to the border of the display region AA, i.e., from the center of the cathode layer 201 to the border of the cathode layer 201, a thickness of the cathode layer 201 gradually decreases, so that the cross-sectional area of the cathode layer 201 gradually decreases, and the unit resistance of the cathode layer 201 gradually increases. As a result, the voltage difference of the first sub-portion 2011, the voltage difference of the second sub-portion 2012, and the voltage difference between the first sub-portion 2011 and the second sub-portion 2012 are further reduced, so that the brightness uniformity of the display panel 100 is further improved.

In some examples, from the center of the display region AA to the border of the display region AA, the thickness of the cathode layer 201 decreases in a gradient manner. For example, the thickness decreases by a proportion in a range of 5% to 15%, inclusive. For instance, the thickness of the cathode layer 201 decreases by 5%, 7%, 8%, 10%, 12% or 15%, which will not be enumerated in the embodiments of the present disclosure.

In some other examples, from the center of the display region AA to the border of the display region AA, the thickness of the cathode layer 201 linearly or curvilinearly decreases. That is, an orthographic projection of a surface of the cathode layer 201 away from the array substrate 10 on a reference plane is in a shape of a straight line or a curve. The reference plane is perpendicular to the array substrate 10 and passes through the center of the display region AA.

In some embodiments, a material of the first sub-portion 2011 includes at least one of aluminum (Al), iron (Fe), tin (Sn), magnesium (Mg), copper (Cu), silver (Ag) and gold (Au), and/or a material of the second sub-portion 2012 includes at least one of aluminum, iron, tin, magnesium, copper, silver and gold.

For example, the material of the first sub-portion 2011 and the material of the second sub-portion 2012 are the same; for instance, the material of the first sub-portion 2011 and the material of the second sub-portion 2012 are both copper. In this way, the material consistency of the cathode layer 201 may be improved and the manufacturing cost of the cathode layer 201 may be reduced.

In a case where the material of the first sub-portion 2011 and the material of the second sub-portion 2012 are both copper, since the light transmittance of copper is relatively low (the light transmittance being less than or equal to 15%), in order to allow the light emitted by the light-emitting function layer 22 to be emitted from the display panel, a material of the anode 23 needs to be a material with a relatively high light transmittance (the light transmittance being greater than or equal to 85%); for example, the material of the anode 23 includes indium tin oxide (ITO). In this case, the light-emitting device 20 is a bottom-emission light-emitting device.

In some other embodiments, the light-emitting device 20 may be top-emission light-emitting device. In this case, the cathode 21 includes a semi-transmissive semi-reflective electrode, which is used to reflect part of the light incident on the cathode 21 and transmit part of the light incident on the cathode 21. The semi-transmissive semi-reflective electrode refers to an electrode with a reflectivity in a range of 50% to 60%, inclusive.

The anode 23 includes a reflective electrode, which is used to reflect light incident on the anode 23. The anode 23 may be of a single-layer structure or a stacked structure; for example, in a case where the anode 23 is of a stacked structure, the anode 23 includes indium tin oxide, silver and indium tin oxide that are stacked. The reflective electrode refers to an electrode with a reflectivity greater than 90%.

The cathode 21 and the anode 23 may form a resonant cavity. The light-emitting function layer 22 is located between the cathode 21 and the anode 23, i.e., the light-emitting function layer 22 is located in the resonant cavity, the intensity of light of a certain wavelength emitted by the light-emitting function layer 22 will be increased, and the spectrum of the light of a certain wavelength emitted by the light-emitting function layer 22 will be narrowed. The resonant cavity may allow most of the light emitted by the light-emitting function layer 22 to be emitted from the display panel 100, thereby improving the luminous efficiency of the light-emitting devices 20.

In some embodiments, an electrical conductivity of the first sub-portion 2011 is greater than an electrical conductivity of the second sub-portion 2012, which makes a resistivity of the first sub-portion 2011 less than a resistivity of the second sub-portion 2012, so that the unit resistance of the first sub-portion 2011 is less than the unit resistance of the second sub-portion 2012. Thus, the voltage difference between the second sub-portion 2012 and the first sub-portion is reduced, so that the brightness uniformity of the display panel 100 is improved.

In some embodiments, the material of the first sub-portion 2011 includes at least one of copper, silver and gold; the material of the second sub-portion 2012 includes at least one of aluminum, iron, tin, and magnesium. The electrical conductivity of copper, silver and gold is greater than that of aluminum, iron, tin and magnesium, so that the electrical conductivity of the first sub-portion 2011 is greater than the electrical conductivity of the second sub-portion 2012. Thus, the voltage difference between the second sub-portion 2012 and the first sub-portion 2011 is reduced, so that the brightness uniformity of the display panel 100 is improved.

For example, the material of the first sub-portion 2011 includes copper, and the material of the second sub-portion 2012 includes aluminum. For another example, the material of the first sub-portion 2011 includes copper, and the material of the second sub-portion 2012 includes tin. For yet another example, the material of the first sub-portion 2011 includes silver, and the material of the second sub-portion 2012 includes aluminum, which will not be enumerated in the embodiments of the present disclosure.

In some embodiments, on the basis that the electrical conductivity of the first sub-portion 2011 is greater than the electrical conductivity of the second sub-portion 2012, the thickness of the first sub-portion 2011 is greater than or equal to the thickness of the second sub-portion 2012.

In some examples, as shown in FIG. 10, the thickness of the first sub-portion 2011 is equal to the thickness of the second sub-portion 2012, so that the thickness of the cathode layer 201 is relatively uniform. When the user applies force on the display panel 100, the force applied to the cathode layer 201 is relatively uniform, so that the force applied to the light-emitting devices 20 is relatively uniform, which may improve the uniformity of the force applied to the light-emitting devices 20 to prolong the service life of the display panel 100.

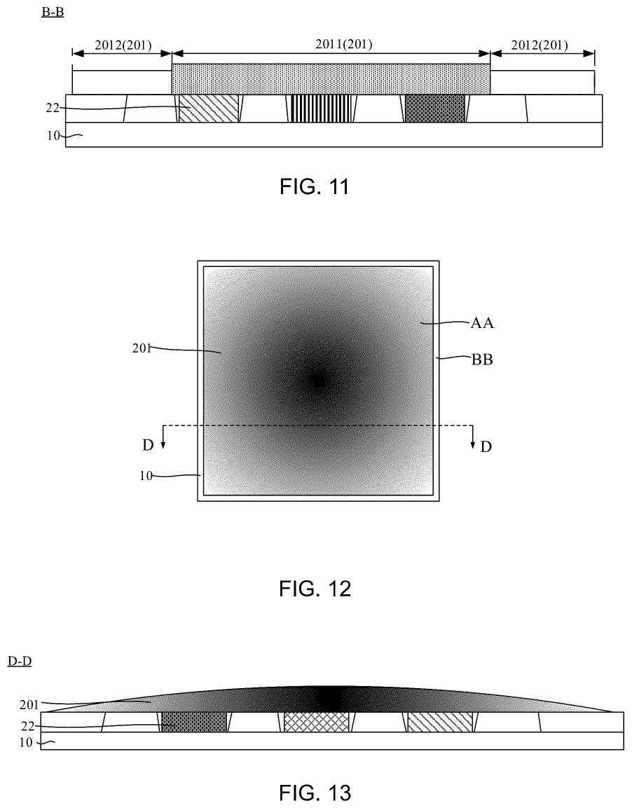

In some other examples, as shown in FIG. 11, the thickness of the first sub-portion 2011 is greater than the thickness of the second sub-portion 2012, so that the cross-sectional area of the first sub-portion 2011 is greater than the cross-sectional area of the second sub-portion 2012, so that the unit resistance of the first sub-portion 2011 is less than the unit resistance of the second sub-portion 2012, which reduces the voltage difference between the first sub-portion 2011 and the second sub-portion 2012 to improve the brightness uniformity of the display panel 100.

In some embodiments, from the center of the display region AA to the border of the display region AA, the electrical conductivity of the cathode layer 201 gradually decreases, which can make the resistivity of the cathode layer 201 gradually increase, so that the unit resistance of the cathode layer 201 gradually increases. As a result, it is possible to further reduce the voltage difference of the first sub-portion 2011, the voltage difference of the second sub-portion 2012, and the voltage difference between the first sub-portion 2011 and the second sub-portion 2012, thereby improving the brightness uniformity of the display panel 100.

In some examples, from the center of the display region AA to the border of the display region AA, the electrical conductivity of the cathode layer 201 decreases in a gradient manner; for example, the electrical conductivity decreases by a proportion in a range of 5% to 15%, inclusive. For example, the electrical conductivity of the cathode layer 201 decreases by 5%, 7%, 8%, 10%, 12% or 15%, which will not be enumerated in the embodiments of the present disclosure.

In some other examples, from the center of the display region AA to the border of the display region AA, the electrical conductivity of the cathode layer 201 linearly or curvilinearly decreases.

In some embodiments, the material of the cathode layer 201 includes a host material and a dopant material, and an electrical conductivity of the host material is greater than or less than the electrical conductivity of the dopant material.

In some examples, the electrical conductivity of the host material is greater than the electrical conductivity of the dopant material. For example, the host material is magnesium and silver, and the dopant material is titanium (Ti).

As shown in FIGS. 12 and 13 (in FIGS. 12 and 13, a darker portion represents a larger ratio of the host material to the dopant material, and a whiter portion represents a smaller ratio of the host material to the dopant material), from the center of the display region AA to the outer border of the display region AA, the ratio of the host material to the dopant material decreases, which can make the electrical conductivity of the cathode layer 201 gradually decrease, so that the resistivity of the cathode layer 201 is gradually increased. As a result, the unit resistance of the cathode layer 201 gradually decreases, thereby improving the brightness uniformity of the display panel 100.

For example, from the center of the display region AA to the outer border of the display region AA, the ratio of the host material to the dopant material decreases in a gradient manner; for example, the ratio decreases by a proportion in a range of 5% to 15%, inclusive. For instance, the ratio of the host material to the dopant material decreases by 5%, 7%, 8%, 10%, 12% or 15%, which will not be enumerated in the embodiments of the present disclosure. Alternatively, for another example, from the center of the display region AA to the outer border of the display region AA, the ratio of the host material to the dopant material linearly or curvilinearly decreases.

In some other examples, the electrical conductivity of the host material is less than the electrical conductivity of the dopant material. For example, the host material is magnesium and silver, and the dopant material is copper.

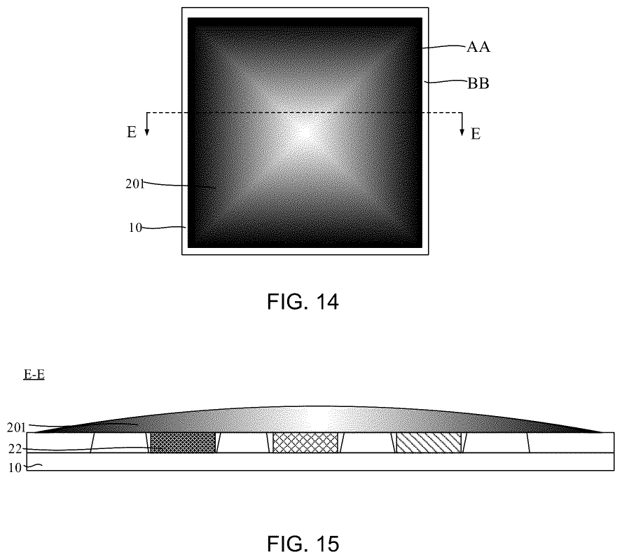

As shown in FIGS. 14 and 15 (in FIGS. 14 and 15, a darker portion represents a larger ratio of the host material to the dopant material, and a whiter portion represents a smaller ratio of the host material to the dopant material), from the center of the display region AA to the outer border of the display region AA, the ratio of the host material to the dopant material increases, which can make the electrical conductivity of the cathode layer 201 gradually decrease, so that the resistivity of the cathode layer 201 is increased. As a result, the unit resistance of the cathode layer 201 is gradually increased, thereby improving the brightness uniformity of the display panel.

For example, from the center of the display region AA to the outer border of the display region AA, the ratio of the host material to the dopant material increases in a gradient manner; for example, the ratio increases by a proportion in a range of 5% to 15%, inclusive. For instance, the ratio of the host material to the dopant material increases by 5%, 7%, 8%, 10%, 12% or 15%, which will not be enumerated in the embodiments of the present disclosure. Alternatively, for another example, from the center of the display region AA to the outer border of the display region AA, the ratio of the host material to the dopant material linearly or curvilinearly increases.

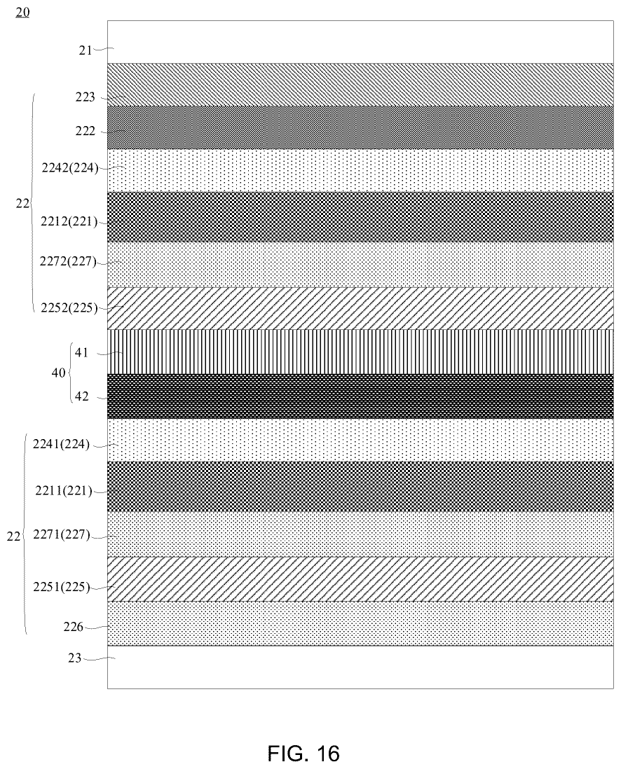

In some embodiments, as shown in FIG. 16, at least two light-emitting layers 221 are disposed between the cathode 21 and the anode 23 that are disposed opposite to each other, and the at least two light-emitting layers 221 are arranged in sequence in a direction perpendicular to the cathode layer 201. The display panel 100 further includes a charge generation layer 40 (CGL); the charge generation layer 40 is located between two adjacent light-emitting layers 221 and is used to provide carriers (holes or electrons) to the two adjacent light-emitting layers 221. In this way, the excitons in the light-emitting function layer 22 in the embodiments of the present disclosure are dispersed in the at least two light-emitting layers 221, which can alleviate the problem of exciton quenching due to relatively high exciton density in a light-emitting layer 221 and can reduce the risk of reduced luminous efficiency of the light-emitting layer 221 due to exciton quenching.

For example, as shown in FIG. 16, the charge generation layer 40 includes a hole charge generation layer 41 and an electron charge generation layer 42, and the hole charge generation layer 41 is closer to the cathode 21 than the electron charge generation layer 42. The hole charge generation layer 41 generates holes due to the action of the cathode 21 and the anode 23, and thus provides the holes to a light-emitting layer 221 proximate to the cathode 21. The electron charge generation layer 42 generates electrons due to the action of the cathode 21 and the anode 23, and thus provides the electrons to a light-emitting layer 221 proximate to the anode 23.

In some embodiments, as shown in FIG. 16, the light-emitting device 20 includes an anode 23, a hole injection layer 226, a first hole transporting layer 2251, a first electron blocking layer 2271, a first light-emitting layer 2211, a first hole blocking layer 2241, an electron charge generation layer 42, a hole charge generation layer 41, a second hole transporting layer 2252, a second electron blocking layer 2272, a second light-emitting layer 2212, a second hole blocking layer 2242, an electron transporting layer 222, an electron injection layer 223 and a cathode 21 that are arranged in a direction perpendicular to the array substrate 10 and away from the array substrate 10.

A thickness of the hole injection layer 226 is in a range of 5 nm to 30 nm, inclusive. For example, the thickness of the hole injection layer 226 is 5 nm, 6 nm, 8 nm, 10 nm, 11 nm, 14 nm, 15 nm, 16 nm, 19 nm, 22 nm, 25 nm, 28 nm or 30 nm, which will not be enumerated in the embodiments of the present disclosure.

A thickness of the first hole transporting layer 2251 is in a range of 100 nm to 130 nm, inclusive. For example, the thickness of the first hole transporting layer 2251 is 100 nm, 102 nm, 105 nm, 108 nm, 110 nm, 113 nm, 117 nm, 120 nm, 121 nm, 124 nm, 126 nm or 130 nm, which will not be enumerated in the embodiments of the present disclosure.

A thickness of the second hole transporting layer 2252 is in a range of 100 nm to 130 nm, inclusive. For example, the thickness of the second hole transporting layer 2252 is 100 nm, 103 nm, 105 nm, 108 nm, 112 nm, 113 nm, 117 nm, 121 nm, 124 nm, 128 nm or 130 nm, which will not be enumerated in the embodiments of the present disclosure.

For example, the thickness of the first hole transporting layer 2251 may be the same as the thickness of the second hole transporting layer 2252. For instance, the thickness of the first hole transporting layer 2251 and the thickness of the second hole transporting layer 2252 are both 100 nm, 105 nm, 108 nm, 113 nm, 121 nm, 126 nm or 130 nm, which will not be enumerated in the embodiments of the present disclosure.

Alternatively, for another example, the thickness of the first hole transporting layer 2251 may be different from the thickness of the second hole transporting layer 2252. For instance, the thickness of the first hole transporting layer 2251 is 100 nm, while the thickness of the second hole transporting layer 2252 is 105 nm; alternatively, the thickness of the first hole transporting layer 2251 is 102 nm, while the thickness of the second hole transporting layer 2252 is 105 nm; alternatively, the thickness of the first hole transporting layer 2251 is 100 nm, while the thickness of the second hole transporting layer 2252 is 121 nm; alternatively, the thickness of the first hole transporting layer 2251 is 110 nm, while the thickness of the second hole transporting layer 2252 is 130 nm, which will not be enumerated in the embodiments of the present disclosure.

A thickness of the first electron blocking layer 2271 is in a range of 10 nm to 80 nm, inclusive. For example, the thickness of the first electron blocking layer 2271 is 10 nm, 14 nm, 20 nm, 28 nm, 32 nm, 40 nm, 50 nm, 65 nm, 70 nm or 80 nm, which will not be enumerated in the embodiments of the present disclosure.

A thickness of the second electron blocking layer 2272 is in a range of 10 nm to 80 nm, inclusive. For example, the thickness of the second electron blocking layer 2272 is 10 nm, 14 nm, 22 nm, 28 nm, 32 nm, 42 nm, 50 nm, 65 nm, 72 nm or 80 nm, which will not be enumerated in the embodiments of the present disclosure.

For example, the thickness of the first electron blocking layer 2271 may be the same as the thickness of the second electron blocking layer 2272. For instance, the thickness of the first electron blocking layer 2271 and the thickness of the second electron blocking layer 2272 are both 10 nm, 14 nm, 20 nm, 28 nm, 32 nm, 40 nm, 50 nm, 65 nm, 70 nm or 80 nm, which will not be enumerated in the embodiments of the present disclosure.

Alternatively, for another example, the thickness of the first electron blocking layer 2271 may be different from the thickness of the second electron blocking layer 2272. For instance, the thickness of the first electron blocking layer 2271 is 10 nm, while the thickness of the second electron blocking layer 2272 is 14 nm; alternatively, the thickness of the first electron blocking layer 2271 is 10 nm, while the thickness of the second electron blocking layer 2272 is 20 nm; alternatively, the thickness of the first electron blocking layer 2271 is 65 nm, while the thickness of the second electron blocking layer 2272 is 50 nm; alternatively, the thickness of the first electron blocking layer 2271 is 70 nm, while the thickness of the second electron blocking layer 2272 is 80 nm, which will not be enumerated in the embodiments of the present disclosure.

A thickness of the first light-emitting layer 2211 is in a range of 20 nm to 40 nm, inclusive. For example, the thickness of the first light-emitting layer 2211 is 20 nm, 22 nm, 25 nm, 26 nm, 28 nm, 29 nm, 31 nm, 34 nm, 35 nm, 38 nm or 40 nm, which will not be enumerated in the embodiments of the present disclosure.

A thickness of the second light-emitting layer 2212 is in a range of 20 nm to 40 nm, inclusive. For example, the thickness of the second light-emitting layer 2212 is 20 nm, 22 nm, 25 nm, 27 nm, 28 nm, 29 nm, 32 nm, 34 nm, 35 nm, 39 nm or 40 nm, which will not be enumerated in the embodiments of the present disclosure.

For example, the thickness of the first light-emitting layer 2211 may be the same as the thickness of the second light-emitting layer 2212. For instance, the thickness of the first light-emitting layer 2211 and the thickness of the second light-emitting layer 2212 are both 20 nm, 22 nm, 25 nm, 26 nm, 28 nm, 29 nm, 31 nm, 34 nm, 35 nm, 38 nm or 40 nm, which will not be enumerated in the embodiments of the present disclosure.

Alternatively, for another example, the thickness of the first light-emitting layer 2211 may be different from the thickness of the second light-emitting layer 2212. For instance, the thickness of the first light-emitting layer 2211 is 20 nm, while the thickness of the second light-emitting layer 2212 is 25 nm; alternatively, the thickness of the first light-emitting layer 2211 is 25 nm, while the thickness of the second light-emitting layer 2212 is 31 nm; alternatively, the thickness of the first light-emitting layer 2211 is 35 nm, while the thickness of the second light-emitting layer 2212 is 34 nm; alternatively, the thickness of the first light-emitting layer 2211 is 38 nm, while the thickness of the second light-emitting layer 2212 is 40 nm, which will not be enumerated in the embodiments of the present disclosure.

A thickness of the first hole blocking layer 2241 is in a range of 5 nm to 10 nm, inclusive. For example, the thickness of the first hole blocking layer is 5 nm, 5.6 nm, 5.8 nm, 6 nm, 6.1 nm, 6.4 nm, 7 nm, 7.2 nm, 7.5 nm, 7.9 nm, 8 nm, 8.5 nm, 9 nm or 10 nm, which will not be enumerated in the embodiments of the present disclosure.

A thickness of the second hole blocking layer 2242 is in a range of 5 nm to 10 nm, inclusive. For example, the thickness of the second hole blocking layer is 5 nm, 5.6 nm, 5.8 nm, 6 nm, 6.2 nm, 6.4 nm, 7 nm, 7.2 nm, 7.6 nm, 7.9 nm, 8 nm, 8.5 nm, 9.1 nm or 10 nm, which will not be enumerated in the embodiments of the present disclosure.

For example, the thickness of the first hole blocking layer 2241 may be the same as the thickness of the second hole blocking layer 2242. For instance, the thickness of the first hole blocking layer 2241 and the thickness of the second hole blocking layer 2242 are both 5 nm, 5.6 nm, 5.8 nm, 6 nm, 6.1 nm, 6.4 nm, 7 nm, 7.2 nm, 7.5 nm, 7.9 nm, 8 nm, 8.5 nm, 9 nm or 10 nm, which will not be enumerated in the embodiments of the present disclosure.

Alternatively, for another example, the thickness of the first hole blocking layer 2241 may be different from the thickness of the second hole blocking layer 2242. For instance, the thickness of the first hole blocking layer 2241 is 5 nm, while the thickness of the second hole blocking layer 2242 is 6 nm; alternatively, the thickness of the first hole blocking layer 2241 is 5 nm, while the thickness of the second hole blocking layer 2242 is 7.2 nm; alternatively, the thickness of the first hole blocking layer 2241 is 8 nm, while the thickness of the second hole blocking layer 2242 is 10 nm; alternatively, the thickness of the first hole blocking layer 2241 is 9 nm, while the thickness of the second hole blocking layer 2242 is 8 nm, which will not be enumerated in the embodiments of the present disclosure.

A thickness of the electron charge generation layer 42 is in a range of 17 nm to 19 nm, inclusive. For example, the thickness of the electron charge generation layer 42 is 17 nm, 17.2 nm, 17.6 nm, 17.9 nm, 18.1 nm, 18.5 nm, 18.8 nm or 19 nm, which will not be enumerated in the embodiments of the present disclosure.

A thickness of the hole charge generation layer 41 is in a range of 8 nm to 10 nm, inclusive. For example, the thickness of the hole charge generation layer 41 is 8 nm, 8.2 nm, 8.6 nm, 8.9 nm, 9 nm, 9.1 nm, 9.5 nm, 9.8 nm or 10 nm, which will not be enumerated in the embodiments of the present disclosure.

The thickness of the electron transporting layer 222 is in a range of 20 nm to 35 nm, inclusive. For example, the thickness of the electron transporting layer 222 is 20 nm, 22 nm, 25 nm, 26 nm, 28 nm, 29 nm, 31 nm, 34 nm or 35 nm, which will not be enumerated in the embodiments of the present disclosure.

The thickness of the electron injection layer 223 is in a range of 0.5 nm to 3 nm, inclusive. For example, the thickness of the electron injection layer 223 is 0.5 nm, 0.6 nm, 0.8 nm, 0.9 nm, 1 nm, 1.5 nm, 2 nm, 2.2 nm, 2.5 nm or 3 nm, which will not be enumerated in the embodiments of the present disclosure. In this way, the color of light emitted by a light-emitting device 20 changes within a same color system.

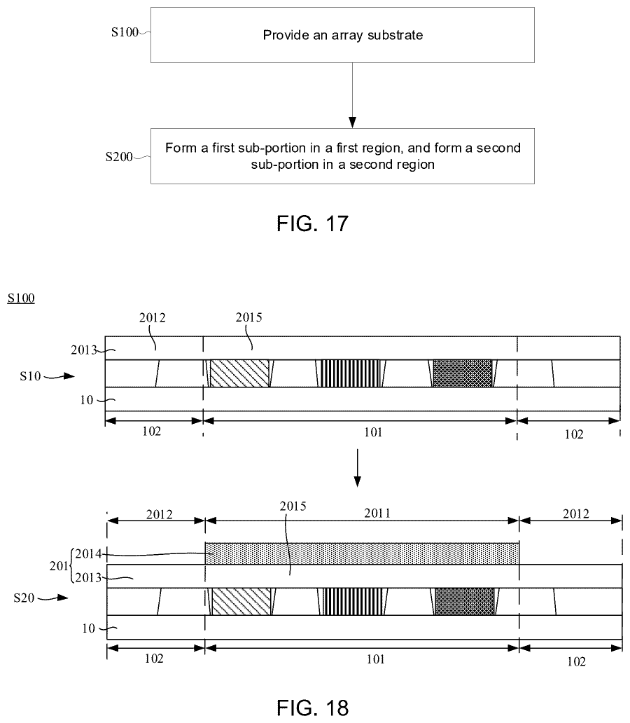

Some embodiments of the present disclosure provide a manufacturing method of a display panel 100, the display panel 100 has a display region AA, and as shown in FIG. 17, the manufacturing method includes S100 to S200.

In S100, an array substrate 10 is provided.

Referring to FIG. 18, the array substrate 10 includes a first region 101 and a second region 102 surrounding the first region 101, and both the first region 101 and the second region 102 are located in the display region AA.

For example, as shown in FIG. 2, the array substrate 10 includes a substrate 11 and pixel circuits 12 disposed on the substrate 11.

In S200, a first sub-portion 2011 is formed in the first region 101, and a second sub-portion 2012 is formed in the second region 102.

The second sub-portion 2012 is connected to the first sub-portion 2011 to constitute a cathode layer 201. The resistance per unit length of the first sub-portion 2011 is less than the resistance per unit length of the second sub-portion 2012. In this way, the voltage difference between the first sub-portion 2011 and the second sub-portion 2012 can be reduced, thereby improving the brightness uniformity of the display panel 100.

In some embodiments, as shown in FIG. 18, S200 (forming the first sub-portion 2011 in the first region 101 and forming the second sub-portion 2012 in the second region 102) includes: S10 to S20.

As shown in FIG. 18, in S10, a first conductive layer 2013 is formed on the array substrate 10.

The first conductive layer 2013 includes a third sub-portion 2015 located in the first region 101 and the second sub-portion 2012 located in the second region 102. For example, the first conductive layer 2013 may be of a whole layer structure covering the array substrate 10.

For example, the first conductive layer 2013 may be formed by a thin film deposition process such as chemical vapor deposition (CVD), physical vapor deposition (PVD), atomic layer deposition (ALD) or any combination thereof.

For example, the material of the first conductive layer 2013 includes at least one of aluminum, iron, tin, magnesium, copper, silver and gold. For instance, the material of the first conductive layer 2013 includes copper.

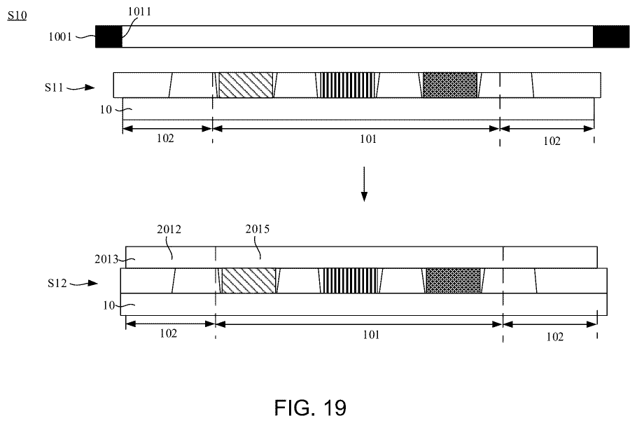

In some examples, as shown in FIG. 19, S10 (forming the first conductive layer 2013 on the array substrate 10) includes: S11 to S12.

In S11, a first mask 1001 is placed on a side of the array substrate 10.

An orthographic projection of a first opening 1011 of the first mask 1001 on the array substrate 10 covers the first region 101 and the second region 102.

In S12, the first conductive layer 2013 is formed through the first opening 1011.

For example, the material of the cathode 21 is deposited on the array substrate 10 by evaporation at a first rate (e.g., the first rate is 2 Å/s) until the thickness of the material of the cathode 21 reaches a first preset thickness (e.g., the first preset thickness may be a designed thickness).

As shown in FIG. 18, in S20, a second conductive layer 2014 is formed on a side of the first conductive layer 2013 away from the array substrate 10.

An orthographic projection of the second conductive layer 2014 on the array substrate 10 coincides with an orthographic projection of the third sub-portion 2015 on the array substrate 10, and the second conductive layer 2014 and the third sub-portion 2015 constitute the first sub-portion 2011.

For example, the material of the second conductive layer 2014 includes at least one of aluminum, iron, tin, magnesium, copper, silver and gold. For instance, the material of the second conductive layer 2014 includes copper.

For example, the material of the second conductive layer 2014 may be the same as the material of the first conductive layer 2013, which may improve the consistency of the material of the display panel to reduce the manufacturing cost of the display panel.

In some examples, S20 (forming the second conductive layer 2014 on a side of the first conductive layer 2013 away from the array substrate 10) includes S21.

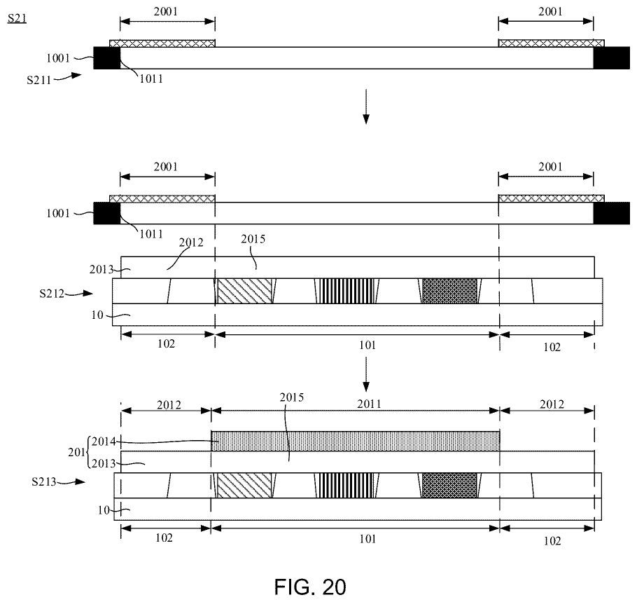

For example, as shown in FIG. 20, S21 includes S211 to S213.

In S211, an edge region 2001 of the first opening 1011 of the first mask 1001 is covered.

In S212, the first mask 1001 of which the edge region 2001 is covered is placed on the side of the first conductive layer 2013 away from the array substrate 10.

The orthographic projection of the first opening 1011 of the first mask 1001 on the array substrate 10 covers the first region 101 and the second region 102, and an orthographic projection of the edge region 2001 on the array substrate 10 covers the second region 102 and exposes the first region 101.

In S213, the second conductive layer 2014 is formed through the first opening 1011.

For example, the material of the cathode 21 is deposited by evaporation at a second rate until the material of the cathode 21 reaches a second preset thickness (e.g., the second preset thickness may be a designed thickness).

For example, the second rate may be equal to the first rate; for instance, the first rate and the second rate are both 2 Å/s.

In some other examples, S20 (forming the second conductive layer 2014 on the first conductive layer 2013) includes S22.

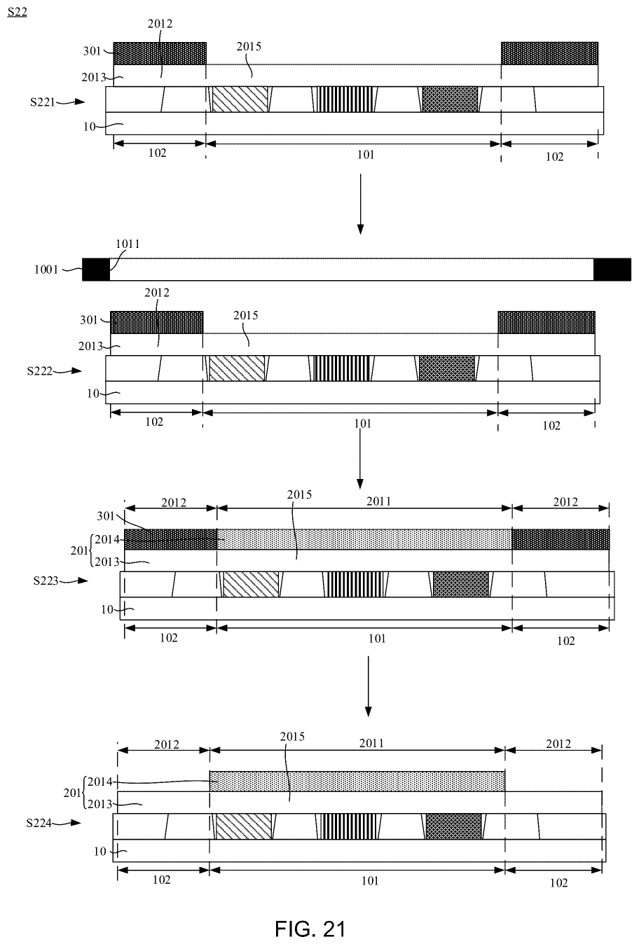

For example, as shown in FIG. 21, S22 include S221 to S224.

In S221, a first metal inhibition layer 301 is formed on a side of the first conductive layer 2013 away from the array substrate 10.

An orthographic projection of the first metal inhibition layer 301 on the array substrate 10 covers the second region 102 and exposes the first region 101.

For example, a material of the first metal inhibition layer 301 may include a cathode patterning material (CPM). The cathode patterning material is a material that only allows the material of the cathode 21 to selectively deposit; that is, in a region with the cathode patterning material, the material of the cathode 21 is difficult to be deposited, but in a region without the cathode patterning material, the material of the cathode 21 may be deposited.

For example, S221 (forming the first metal inhibition layer 301 on a side of the first conductive layer 2013 away from the array substrate 10) includes: S2211 to S2213.

In S2211, a central region of the first opening of the first mask is covered.

In S2212, the first mask of which the central region is covered is placed on a side of the first conductive layer away from the array substrate 10.

The orthographic projection of the first opening of the first mask on the array substrate 10 covers the first region and the second region, and an orthographic projection of the central region on the array substrate 10 covers the first region and exposes the second region.

In S2213, a first metal inhibition layer is formed through the first opening.

Alternatively, for another example, S221 (forming the first metal inhibition layer 301 on the side of the first conductive layer 2013 away from the array substrate 10) includes: S2214 to S2215.

In S2214, a sixth mask is placed on a side of the first conductive layer away from the array substrate; an orthographic projection of a sixth opening of the sixth mask on the array substrate 10 covers the second region and exposes the first region.

In S2215, a first metal inhibition layer is formed through the sixth opening.

As shown in FIG. 21, in S222, the first mask 1001 is placed on the side of the first conductive layer 2013 away from the array substrate 10.

The orthographic projection of the first opening 1011 on the array substrate 10 covers the first region 101 and the second region 102.

As shown in FIG. 21, in S223, the second conductive layer 2014 is formed through the first opening 1011 and the first metal inhibition layer 301.

The orthographic projection of the first metal inhibition layer 301 on the array substrate 10 covers the second region 102 and exposes the first region 101, so that the material of the cathode 21 is less or even not deposited in the second region 102; that is, the material of the cathode 21 will not form a continuous layered structure on the first metal inhibition layer 301, and the material of the cathode 21 forms a continuous layered structure in a region without the first metal inhibition layer 301.

As shown in FIG. 21, in S224, the first metal inhibition layer 301 is removed.

The cathode layer 201 may also be patterned by using the cathode patterning material. For example, the orthographic projection of the cathode layer 201 on the array substrate 10 partially overlaps with orthographic projections of the light-emitting layers 221 on the array substrate 10; that is, there is no cathode layer 201 in some regions on the light-emitting layers 221, and the light emitted from the light-emitting layer 221 may be emitted from the light-emitting devices 20 from these regions, thereby increasing the light transmittance of the cathode layer 201.

In a case where the patterned cathode layer 201 is applied to the field of under-screen technology, the patterned cathode layer 201 has a relatively high light transmittance, and most of the external light can be directed into the functional devices (e.g., a front camera component, a under-screen fingerprint component, a 3D face recognition component, an iris recognition component, a proximity sensor, and other devices that can realize specific functions) in the field of under-screen technology, thereby improving the sensitivity of the functional devices.

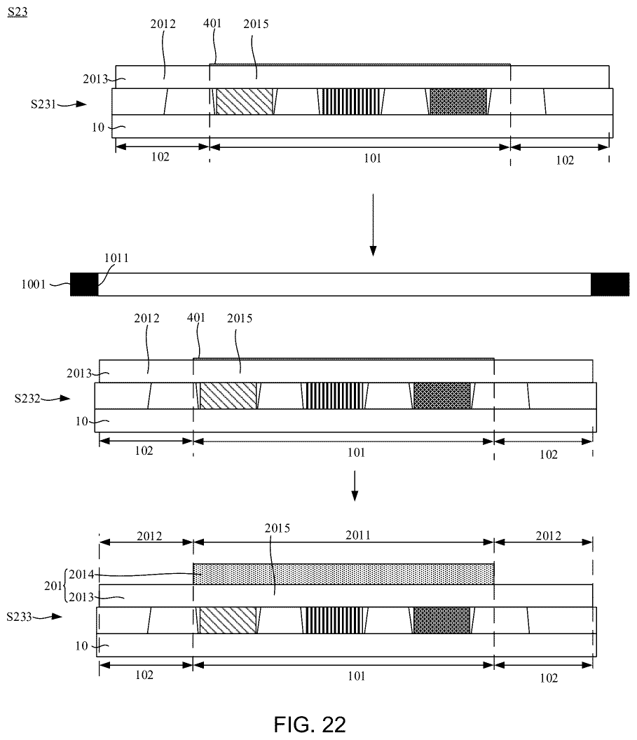

In some other embodiments, as shown in FIG. 22, S20 (forming the second conductive layer 2014 on the first conductive layer 2013) includes S23.

As shown in FIG. 22, for example, S23 includes: S231 to S233.

In S231, a metal promotion layer 401 is formed on the first conductive layer 2013.

An orthographic projection of the metal promotion layer 401 on the array substrate 10 covers the first region 101 and exposes the second region 102.

For example, a thickness of the metal promotion layer 401 is less than the thickness of the first conductive layer 2013; that is, the metal promotion layer 401 is relatively thin, which may reduce the thickness of the light-emitting devices 20, so as to reduce the thickness of the display panel 100 to facilitate the thinness and lightness of the display device 1000.

For example, S231 (forming the metal promotion layer 401 on the first conductive layer 2013) includes: S2311 to S2313.

In S2311, an edge region of the first opening of the first mask is covered;

In S2312, the first mask of which edge region is covered is placed on the side of the first conductive layer away from the array substrate.

The orthographic projection of the first opening of the first mask on the array substrate covers the first region and the second region, and an orthographic projection of the edge region on the array substrate covers the second region and exposes the first region.

In S2313, the metal promotion layer is formed through the first opening.

Alternatively, for another example, S231 (forming the metal promotion layer 401 on the first conductive layer 2013) includes: S2314 to S2315.

In S2314, a second mask is placed on the side of the first conductive layer 2013 away from the array substrate 10.

An orthographic projection of a second opening of the second mask on the array substrate covers the first region and exposes the second region.

In S2315, the metal promotion layer 401 is formed through the second opening.

As shown in FIG. 22, in S232, the first mask 1001 is placed on a side of the first conductive layer 2013 and the metal promotion layer 401 away from the array substrate 10.

The orthographic projection of the first opening 1011 of the first mask 1001 on the array substrate 10 covers the second region 102 and the first region.

As shown in FIG. 22, in S233, the second conductive layer 2014 is formed through the first opening 1011 and the metal promotion layer 401.

The metal promotion layer 401 is configured such that the orthographic projection of the second conductive layer 2014 on the array substrate 10 is located in the first region 101 and exposes the second region 102.

In some other examples, S20 (forming the second conductive layer 2014 on the side of the first conductive layer 2013 away from the array substrate 10) includes S24.

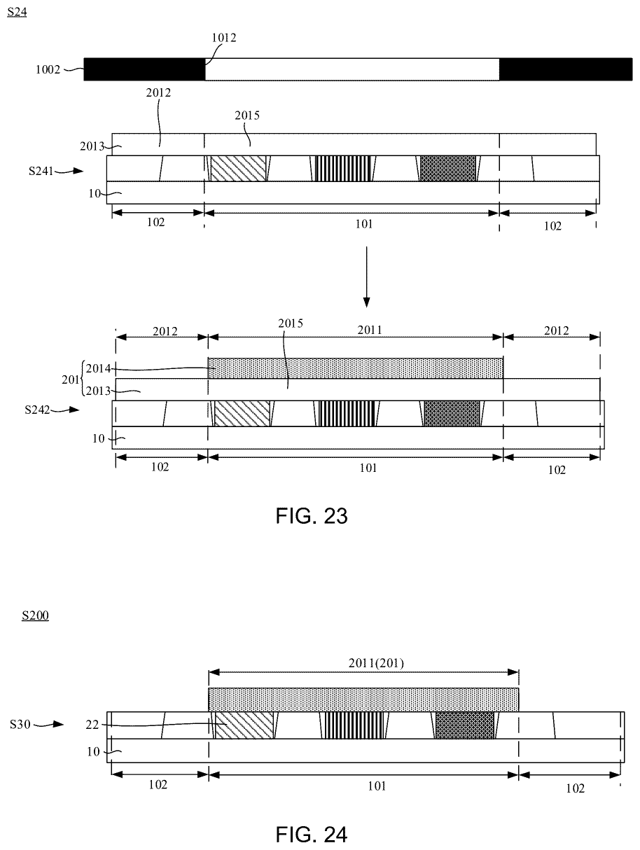

For example, as shown in FIG. 23, S24 includes S241 to S242.

In S241, a second mask 1002 is placed on the side of the first conductive layer 2013 away from the array substrate 10.

An orthographic projection of a second opening 1012 of the second mask 1002 on the array substrate 10 covers the first region 101 and exposes the second region 102.

In S242, the second conductive layer 2014 is formed through the second mask 1002.

For example, the material of the cathode 21 is deposited by evaporation at a second rate until the material of the cathode 21 reaches a second preset thickness (e.g., the second preset thickness may be a designed thickness).

In some other embodiments, S200 (forming the first sub-portion 2011 in the first region 101 and forming the second sub-portion 2012 in the second region 102) includes: S30 to S40.

As shown in FIG. 24, in S30, the first sub-portion 2011 is formed in the first region 101.

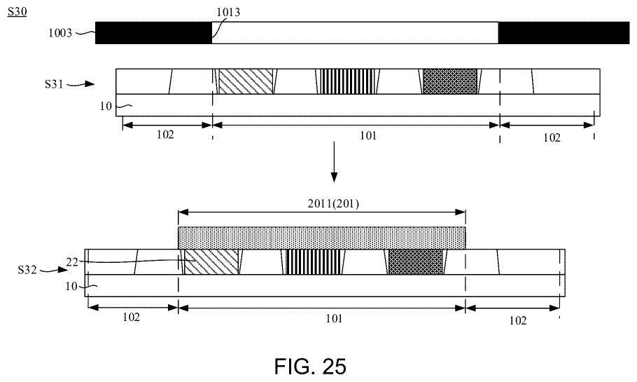

In some examples, as shown in FIG. 25, S30 (forming the first sub-portion 2011 in the first region 101) includes: S31 to S32.

In S31, a third mask 1003 is placed on a side of the array substrate 10.

The third mask 1003 has a third opening region 1013, and an orthographic projection of the third opening region 1013 on the array substrate 10 covers the first region 101 and exposes the second region 102.

For example, the edge region 2001 of the first opening 1011 of the first mask 1001 is covered, the covered first mask 1001 serves as the third mask 1003, and a region of the first opening 1011 that is not covered forms the third opening region 1013.

Alternatively, for another example, the second mask 1002 directly serves as the third mask 1003, and the second opening 1012 of the second mask 1002 forms the third opening region 1013.

In S32, the first sub-portion 2011 is formed through the third opening region 1013.

For example, the material of the cathode 21 is deposited on the array substrate 10 by evaporation at a third rate (e.g., the third rate is 2 Å/s) until the thickness of the material of the cathode 21 reaches a third preset thickness (e.g., the third preset thickness may be a designed thickness).

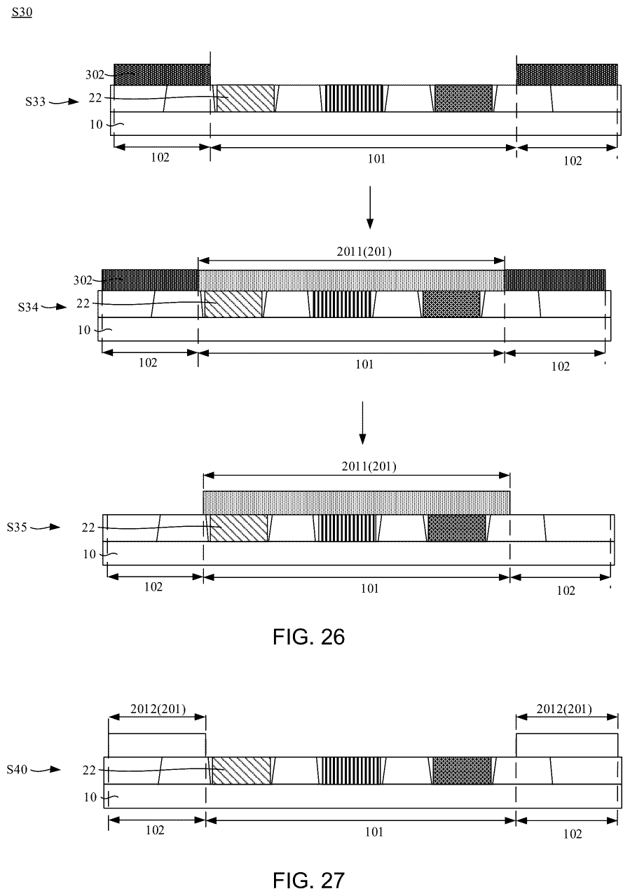

In some other examples, as shown in FIG. 26, S30 (forming the first sub-portion 2011 in the first region 101) includes: S33 to S35.

As shown in FIG. 26, in S33, a second metal inhibition layer 302 is formed on the array substrate 10.

An orthographic projection of the second metal inhibition layer 302 on the array substrate 10 covers the second region 102 and exposes the first region 101. A material of the second metal inhibition layer 302 may include a cathode patterning material.

For example, S33 (forming the second metal inhibition layer 302 on the array substrate 10) includes: S331 to S333.

In S331, a central region of the first opening of the first mask is covered.

In S332, the first mask of which the central region is covered is placed on a side of the first conductive layer away from the array substrate.

The orthographic projection of the first opening of the first mask on the array substrate covers the first region and the second region, and an orthographic projection of the central region on the array substrate covers the first region and exposes the second region.

In S333, the second metal inhibition layer is formed through the first opening.

Alternatively, for another example, S33 (forming the second metal inhibition layer 302 on the array substrate 10) includes: S334 to S335.

In S334, a sixth mask is placed on a side of the first conductive layer away from the array substrate.

An orthographic projection of a sixth opening of the sixth mask on the array substrate covers the second region and exposes the first region.

In S335, the second metal inhibition layer is formed through the sixth opening.

As shown in FIG. 26, in S34, the first sub-portion 2011 is formed through the second metal inhibition layer 302.

The orthographic projection of the second metal inhibition layer 302 on the array substrate 10 covers the second region 102 and exposes the first region 101, so that the material of the cathode 21 is less or even not deposited in the second region 102; that is, the material of the cathode 21 will not form a continuous layered structure on the second metal inhibition layer 302, and the material of the cathode 21 forms a continuous layered structure only in a region without the second metal inhibition layer 302.

As shown in FIG. 26, in S35, the second metal inhibition layer 302 is removed.

As shown in FIG. 27, in S40, the second sub-portion 2012 is formed in the second region 102.

For example, the electrical conductivity of the first sub-portion 2011 is greater than the electrical conductivity of the second sub-portion 2012, which can make the resistivity of the first sub-portion 2011 less than the resistivity of the second sub-portion 2012, so that the unit resistance of the first sub-portion 2011 is less than the unit resistance of the second sub-portion 2012, the voltage difference between the second sub-portion 2012 and the first sub-portion is reduced, and the brightness uniformity of the display panel is improved.

In the case where the electrical conductivity of the first sub-portion 2011 is greater than the electrical conductivity of the second sub-portion 2012, the thickness of the first sub-portion 2011 may be equal to the thickness of the second sub-portion 2012, so that the thickness of the cathode layer 201 may be relatively uniform. When the user applies force to the cathode layer 201, the force applied to the cathode layer 201 is relatively uniform, so that the force applied to the light-emitting devices 20 is relatively uniform, which may improve the uniformity of the force applied to the light-emitting devices 20 and prolong the service life of the dimming display panel.

For example, the thickness of the first sub-portion 2011 is greater than the thickness of the second sub-portion 2012, so that the cross-sectional area of the first sub-portion 2011 is greater than the cross-sectional area of the second sub-portion 2012. As a result, the unit resistance of the first sub-portion 2011 is less than the unit resistance of the second sub-portion 2012, which can reduce the voltage difference between the first sub-portion 2011 and the second sub-portion 2012, thereby improving the brightness uniformity of the display panel.

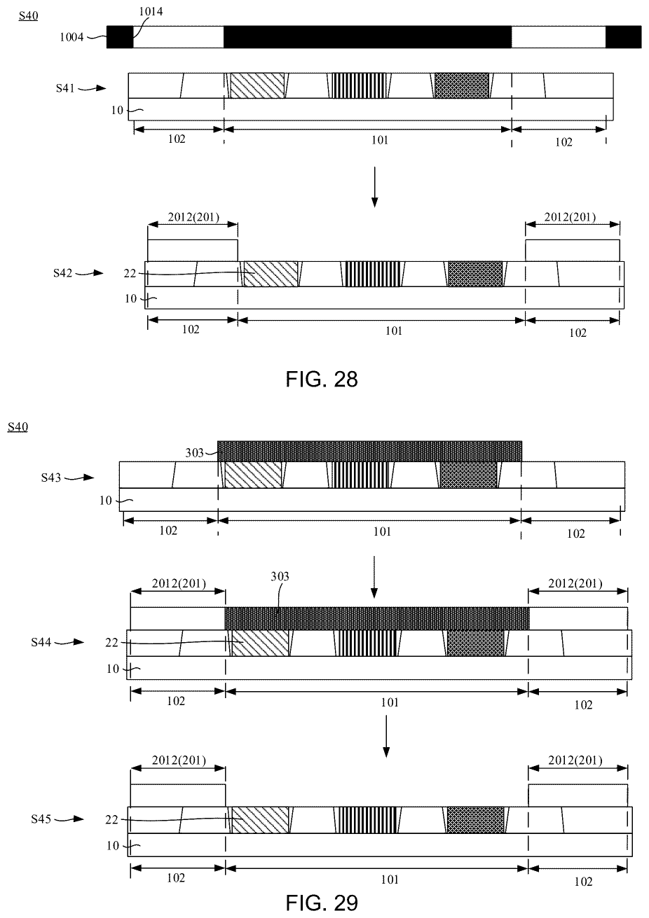

In some examples, as shown in FIG. 28, S40 (forming the second sub-portion 2012 in the second region 102) includes: S41 to S42.

In S41, a fourth mask 1004 is placed on a side of the array substrate 10.

The fourth mask 1004 has a fourth opening region 1014, and an orthographic projection of the fourth opening region 1014 on the array substrate 10 covers the second region 102 and exposes the first region 101.

For example, the central region of the first opening 1011 of the first mask 1001 is covered, the covered first mask 1001 serves as the fourth mask 1004, and a region of the first opening 1011 that is not covered forms the fourth opening region 1014.

Alternatively, for another example, the sixth mask directly serves as the fourth mask 1004, and the sixth opening of the sixth mask forms the fourth opening region 1014.

In S42, the second sub-portion 2012 is formed through the fourth opening region 1014.

For example, the material of the cathode 21 is deposited on the array substrate 10 by evaporation at a fourth rate (e.g., the fourth rate is 2 Å/s) until the thickness of the material of the cathode 21 reaches a fourth preset thickness (e.g., the fourth preset thickness may be a designed thickness).

In a case where the thickness of the first sub-portion 2011 is greater than the thickness of the second sub-portion 2012, the third rate may be greater than the fourth rate; for example, the third rate is 2 Å/s and the fourth rate is 1 Å/s.

In some other examples, as shown in FIG. 29, S40 (forming the second sub-portion 2012 in the second region 102) includes: S43 to S45.

As shown in FIG. 29, in S43, a third metal inhibition layer 303 is formed on the array substrate 10.

An orthographic projection of the third metal inhibition layer 303 on the array substrate 10 covers the first region 101 and exposes the second region 102. A material of the third metal inhibition layer 303 may include a cathode patterning material.

For example, S43 (forming the third metal inhibition layer 303 on the array substrate 10) includes: S431 to S433.

In S431, an edge region of the first opening of the first mask is covered.

In S432, the first mask of which the edge region is covered is placed on a side of the first conductive layer away from the array substrate.

The orthographic projection of the first opening of the first mask on the array substrate 10 covers the first region and the second region, and the orthographic projection of the edge region on the array substrate covers the second region and exposes the first region.

In S433, the third metal inhibition layer is formed through the first opening.

Alternatively, for another example, S43 (forming the third metal inhibition layer 303 on the array substrate 10) includes: S434 to S435.

In S434, the second mask is placed on a side of the first conductive layer away from the array substrate.

The orthographic projection of the second opening of the second mask on the array substrate covers the first region and exposes the second region.

In S435, the third metal inhibition layer is formed through the second opening.

As shown in FIG. 29, in S44, the second sub-portion 2012 is formed through the third metal inhibition layer 303.

An orthographic projection of the third metal inhibition layer 303 on the array substrate 10 covers the first region 101 and exposes the second region 102, so that the material of the cathode 21 is less or even not deposited in the first region 101; that is, the material of the cathode 21 will not form a continuous layered structure on the third metal inhibition layer 303, and the material of the cathode 21 forms a continuous layered structure only in a region without the third metal inhibition layer 303.

In S45, the third metal inhibition layer 303 is removed.

It will be understood that, the order of step S30 and step S40 may be interchanged; that is, S30 and S40 may be performed in sequence, or S40 may be performed before S30.

In some other embodiments, S200 (forming the first sub-portion 2011 in the first region 101 and forming the second sub-portion 2012 in the second region 102) includes S50 to S60.

In S50, a fifth mask is placed on a side of the array substrate 10.

The fifth mask has a fifth opening region, and the fifth opening region is located in the display region.

For example, the edge region 2001 of the first opening 1011 of the first mask 1001 is covered, the covered first mask 1001 serves as the fifth mask, and a region of the first opening 1011 that is not covered forms the fifth opening region.

Alternatively, for another example, the second mask 1002 directly serves as the fifth mask, and the second opening 1012 of the second mask 1002 forms the fifth opening region.

In S60, an area of the fifth opening region is gradually increased, and the material of the cathode 21 is deposited on the array substrate 10 through the fifth opening region by evaporation to form the cathode layer 201.

For example, the area of the fifth opening region is increased in a gradient manner; for instance, the area is increased by a proportion in a range of 5% to 15%, inclusive. For example, the area of the fifth opening region is increased by 5%, 7%, 8%, 10%, 12% or 15%, which will not be individually enumerated in the embodiments of the present disclosure.

For example, in a case where the covered first mask 1001 serves as the fifth mask, the area of the covered region of the first opening 1011 needs to be reduced to increase the area of the fifth opening region.

Alternatively, for another example, in a case where the second mask 1002 directly serves as the fifth mask, the mask needs to be replaced, and the area of the opening of the replaced mask should be increased.

For example, after the area of the fifth opening region is increased, the rate at which the material of the cathode 21 is deposited on the array substrate 10 by evaporation may be reduced. For instance, the rate of the first evaporation deposition process on the array substrate 10 is 3 Å/s. Next, the area of the fifth opening region is increased, and the rate at which the material of the cathode 21 is deposited by evaporation is reduced; for instance, the rate of the second evaporation deposition process on the array substrate 10 is 2.5 Å/s. Then, the area of the fifth opening region is further increased, and the rate at which the material of the cathode 21 is deposited by evaporation is further reduced; for instance, the rate of the third evaporation deposition process on the array substrate 10 is 2 Å/s.

In some embodiments, the manufacturing method further includes S601 while S60 (gradually increasing the area of the fifth opening region) is performed.

In S601, an electrical conductivity of the material of the cathode 21 to be deposited by evaporation is gradually reduced.

For example, the electrical conductivity of the cathode layer 201 is reduced in a gradient manner; for instance, the electrical conductivity is reduced by a proportion in a range of 5% to 15%, inclusive. For example, the electrical conductivity of the cathode layer 201 is reduced by 5%, 7%, 8%, 10%, 12% or 15%, which will not be enumerated in the embodiments of the present disclosure.

In some examples, the material of the cathode 21 includes a host material and a dopant material. The electrical conductivity of the host material is greater than or less than the electrical conductivity of the dopant material.

For example, the electrical conductivity of the host material is greater than the electrical conductivity of the dopant material, and the ratio of the host material to the dopant material is gradually reduced.

Alternatively, for another example, the electrical conductivity of the host material is less than the electrical conductivity of the dopant material, and the ratio of the host material to the dopant material is gradually increased.

In the description of the present specification, specific features, structures, materials or characteristics may be combined in a suitable manner in any one or more embodiments or examples.

The above are only specific embodiments of the present disclosure, but the protection scope of the present disclosure is not limited thereto, and variations or substitutions that any person skilled in the art may conceive of within the technical scope of the present disclosure should fall within the protection scope of the present disclosure. Therefore, the protection scope of the present disclosure should be determined by the protection scope of the claims.

1. A display panel having a display region, wherein the display panel comprises:
an array substrate; and
a cathode layer disposed on the array substrate, wherein the cathode layer includes a first sub-portion and a second sub-portion surrounding the first sub-portion, both the first sub-portion and the second sub-portion are located in the display region, and a resistance per unit length of the first sub-portion is less than a resistance per unit length of the second sub-portion.

2. The display panel according to claim 1, wherein a thickness of the first sub-portion is greater than a thickness of the second sub-portion.

3. The display panel according to claim 2, wherein the cathode layer includes:
a first conductive layer disposed on the array substrate and located in the display region, wherein the first conductive layer includes a third sub-portion and the second sub-portion surrounding the third sub-portion; and
a second conductive layer disposed on a side of the first conductive layer away from the array substrate, wherein an orthographic projection of the second conductive layer on the array substrate coincides with an orthographic projection of the third sub-portion on the array substrate, and the second conductive layer and the third sub-portion constitute the first sub-portion.

4. The display panel according to claim 3, wherein the display panel further comprises:
a plurality of light-emitting devices disposed on the array substrate, wherein in a direction perpendicular to the array substrate and away from the array substrate, a light-emitting device of the plurality of light-emitting devices includes a light-emitting function layer and a cathode that are stacked; the cathode is located in the cathode layer, and an orthographic projection of the second conductive layer on the array substrate partially overlaps with orthographic projections of a plurality of light-emitting function layers included in the plurality of the light-emitting devices on the array substrate.

5. The display panel according to claim 1, wherein from a center of the display region to a border of the display region, a thickness of the cathode layer gradually decreases.

6. The display panel according to claim 2, wherein a material of the first sub-portion includes at least one of aluminum, iron, tin, magnesium, copper, silver and gold, and/or a material of the second sub-portion includes at least one of aluminum, iron, tin, magnesium, copper, silver and gold.

7. The display panel according to claim 1, wherein an electrical conductivity of the first sub-portion is greater than an electrical conductivity of the second sub-portion.

8. The display panel according to claim 7, wherein a material of the first sub-portion includes at least one of copper, silver and gold, and a material of the second sub-portion includes at least one of aluminum, iron, tin and magnesium; and/or
a thickness of the first sub-portion is greater than or equal to a thickness of the second sub-portion.

9. The display panel according to claim 1, wherein from a center of the display region to a border of the display region, an electrical conductivity of the cathode layer gradually decreases.

10. The display panel according to claim 9, wherein a material of the cathode layer includes a host material and a dopant material; and
an electrical conductivity of the host material is greater than an electrical conductivity of the dopant material, and from the center of the display region to the border of the display region, a ratio of the host material to the dopant material decreases; or
the electrical conductivity of the host material is less than the electrical conductivity of the dopant material, and from the center of the display region to the border of the display region, the ratio of the host material to the dopant material increases.

11. (canceled)

12. A display device, comprising: the display panel according to claim 1.

13. A manufacturing method of a display panel, wherein the display panel has a display region, and the manufacturing method comprises:
providing an array substrate, wherein the array substrate includes a first region and a second region surrounding the first region, and both the first region and the second region are located in the display region; and
forming a first sub-portion in the first region and forming a second sub-portion in the second region, wherein the second sub-portion is connected to the first sub-portion to constitute a cathode layer, and a resistance per unit length of the first sub-portion is less than a resistance per unit length of the second sub-portion.

14. The manufacturing method according to claim 13, wherein forming the first sub-portion in the first region and forming the second sub-portion in the second region includes:
forming a first conductive layer on the array substrate, wherein the first conductive layer includes a third sub-portion located in the first region and the second sub-portion located in the second region; and
forming a second conductive layer on a side of the first conductive layer away from the array substrate, wherein an orthographic projection of the second conductive layer on the array substrate coincides with an orthographic projection of the third sub-portion on the array substrate, and the second conductive layer and the third sub-portion constitute the first sub-portion.

15. The manufacturing method according to claim 14, wherein forming the first conductive layer on the array substrate includes:
placing a first mask on a side of the array substrate, wherein an orthographic projection of a first opening of the first mask on the array substrate covers the first region and the second region; and
forming the first conductive layer through the first opening.

16. The manufacturing method according to claim 14, wherein forming the second conductive layer on the side of the first conductive layer away from the array substrate includes:
covering an edge region of a first opening of a first mask;
placing the first mask of which the edge region is covered on the side of the first conductive layer away from the array substrate, wherein an orthographic projection of the first opening on the array substrate covers the first region and the second region, and an orthographic projection of the edge region on the array substrate covers the second region and exposes the first region; and
forming the second conductive layer through the first opening; or
forming the second conductive layer on the side of the first conductive layer away from the array substrate includes:
placing a second mask on the side of the first conductive layer away from the array substrate, wherein an orthographic projection of a second opening of the second mask on the array substrate covers the first region and exposes the second region; and
forming the second conductive layer through the second opening.

17. The manufacturing method according to claim 14, wherein forming the second conductive layer on the side of the first conductive layer away from the array substrate includes:
forming a first metal inhibition layer on the side of the first conductive layer away from the array substrate, wherein an orthographic projection of the first metal inhibition layer on the array substrate covers the second region and exposes the first region;
placing a first mask on the side of the first conductive layer away from the array substrate, wherein an orthographic projection of a first opening of the first mask on the array substrate covers the first region and the second region;
forming the second conductive layer through the first opening and the first metal inhibition layer; and
removing the first metal inhibition layer; or
forming the second conductive layer on the side of the first conductive layer away from the array substrate includes:
forming a metal promotion layer on the first conductive layer, wherein an orthographic projection of the metal promotion layer on the array substrate covers the first region layer away from the array substrate; and
forming the second conductive layer through the first opening and the metal promotion layer, wherein the metal promotion layer is configured such that the orthographic projection of the second conductive layer on the array substrate is located in the first region and exposes the second region.

18. (canceled)

19. (canceled)

20. The manufacturing method according to claim 13, wherein forming the first sub-portion in the first region includes:
placing a third mask on a side of the array substrate, wherein the third mask has a third opening region, and an orthographic projection of the third opening region on the array substrate covers the first region and exposes the second region; and
forming the first sub-portion through the third opening region; or
forming the first sub-portion in the first region includes:
forming a second metal inhibition layer on the array substrate, wherein an orthographic projection of the second metal inhibition layer on the array substrate covers the second region and exposes the first region;
forming the first sub-portion through the second metal inhibition layer; and
removing the second metal inhibition layer.

21. (canceled)

22. The manufacturing method according to claim 20, wherein forming the second sub-portion in the second region includes:
placing a fourth mask on a side of the array substrate, wherein the fourth mask has a fourth opening region, and an orthographic projection of the fourth opening region on the array substrate covers the second region and exposes the first region; and
forming the second sub-portion through the fourth opening region, wherein a thickness of the first sub-portion is greater than a thickness of the second sub-portion, and/or an electrical conductivity of the first sub-portion is greater than an electrical conductivity of the second sub-portion; or
forming the second sub-portion in the second region includes:
forming a third metal inhibition layer on the array substrate, wherein an orthographic projection of the third metal inhibition layer on the array substrate covers the first region and exposes the second region;
forming the second sub-portion through the third metal inhibition layer, wherein the thickness of the first sub-portion is greater than the thickness of the second sub-portion, and/or the electrical conductivity of the first sub-portion is greater than the electrical conductivity of the second sub-portion; and
removing the third metal inhibition layer.

23. (canceled)

24. The manufacturing method according to claim 13, wherein forming the first sub-portion in the first region and forming the second sub-portion in the second region includes:
placing a fifth mask on a side of the array substrate, wherein the fifth mask has a fifth opening region located in the display region; and
gradually increasing an area of the fifth opening region and depositing a cathode material on the array substrate through the fifth opening region by evaporation to form the cathode layer, wherein from a center of the display region to a border of the display region, a thickness of the cathode layer gradually decreases.

25. The manufacturing method according to claim 24, wherein while increasing the area of the fifth opening region, the manufacturing method further comprises:
gradually reducing an electrical conductivity of the cathode material to be deposited by evaporation, wherein the cathode material includes a host material and a dopant material, wherein
an electrical conductivity of the host material is greater than an electrical conductivity of the dopant material, and a ratio of the host material to the dopant material is gradually reduced; or
the electrical conductivity of the host material is less than the electrical conductivity of the dopant material, and the ratio of the host material to the dopant material is gradually increased.
